(19) United States
(12) Patent Application Publication
(10) Pub. No.: US 2023/0307457 A1
(43) Pub. Date: Sep. 28, 2023

(54) SEMICONDUCTOR DEVICE AND METHOD OF FORMING THE SAME

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Wei-Cheng KANG, Tainan City (TW); Tzu-Hsuan CHANG, Taipei City (TW); Wei-Yang WENG, Kaohsiung City (TW); Yu-Tzu CHENG, Miaoli County (TW); Huang-Chun HSU, Yunlin County (TW); Yu-Jung LIAO, Miaoli County (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 17/871,451

(22) Filed: Jul. 22, 2022

Related U.S. Application Data
(60) Provisional application No. 63/332,626, filed on Apr. 19, 2022.
(60) Provisional application No. 63/323,447, filed on Mar. 24, 2022.

(51) Int. Cl. H01L 27/118

(52) U.S. Cl. CPC H01L 27/11807; H01L 2027/11853; H01L 2027/11881; H03K 19/20

(57) ABSTRACT

A semiconductor device having a standard cell comprises a first bottom transistor, a first top transistor, a second bottom transistor, a second top transistor, and a first bottom-transistor-level metal line. The first bottom transistor is in a first row. The first top transistor is disposed above the first bottom transistor in the first row. The first bottom transistor and the first top transistor share a first gate structure. The second bottom transistor is in a second row next to the first row. The second top transistor is disposed above the second bottom transistor in the second row. The second bottom transistor and the second top transistor share a second gate structure. The first bottom-transistor-level metal line extends laterally from a first source/drain region of the first bottom transistor to a source/drain region of the second bottom transistor.

### PRIORITY CLAIM AND CROSS-REFERENCE

This application claims priority to U.S. Provisional Patent Application No. 63/323,447, filed Mar. 24, 2022, and U.S. Provisional Patent Application No. 63/332,626, filed Apr. 19, 2022, all of which are incorporated herein by reference in their entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an example CFET.

FIGS. 2-7A, 8-10A, and 11-12A, and 13 are perspective views of intermediate stages in manufacturing of the DCH CFET standard cell.

FIGS. 7B-7C are cross-sectional views of intermediate stages of example manufacturing processes illustrated in FIG. 7A.

FIGS. 10B-10F are cross-sectional views of intermediate stages of example manufacturing processes illustrated in FIG. 10A.

FIGS. 12B-12D are cross-sectional views of intermediate stages of example manufacturing processes illustrated in FIG. 12A.

FIG. 14A is a circuit diagram of an AOI21 logic gate.

FIG. 14B is a top view layout diagram of an AOI21 logic cell implemented using the DCH standard cell design in accordance with some embodiments of the present disclosure, wherein FIG. 14B illustrates a combined layout including a layout of top transistor level and a layout of bottom transistor level.

FIG. 14C is a cross-sectional view combining a cross-sectional cut C1-C1 on the top transistor level and a cross-sectional cut C2-C2 on the bottom transistor level illustrated in FIG. 14B.

FIG. 14D is a cross-sectional view combining a cross-sectional cut D1-D1 on the top transistor level and a cross-sectional cut D2-D2 on the bottom transistor level illustrated in FIG. 14B.

FIG. 14E is a cross-sectional view combining a cross-sectional cut E1-E1 on the top transistor level and a cross-sectional cut E2-E2 on the bottom transistor level illustrated in FIG. 14B.

FIG. 14F is a cross-sectional view combining a cross-sectional cut F1-F1 on the top transistor level and a cross-sectional cut F2-F2 on the bottom transistor level illustrated in FIG. 14B.

FIG. 15A is a top view layout diagram illustrating routing congestion improvement of an AOI21 cell in accordance with some embodiments of the present disclosure, wherein FIG. 15A illustrates a combined layout including a layout of top transistor level and a layout of bottom transistor level.

FIG. 15B is a cross-sectional view combining a cross-sectional cut B1-B1 on the top transistor level and a cross-sectional cut B2-B2 on the bottom transistor level illustrated in FIG. 15A.

FIG. 15C is a cross-sectional view combining a cross-sectional cut C1-C1 on the top transistor level and a cross-sectional cut C2-C2 on the bottom transistor level illustrated in FIG. 15A.

FIG. 16A is a top view layout diagram of a standard cell in accordance with some embodiments of the present disclosure, wherein FIG. 16A illustrates a layout of BEOL metal level, a layout of top transistor level and a layout of bottom transistor level.

FIG. 16B is a cross-sectional view combining a cross-section of output node (denoted as “OUT”) on the bottom transistor level, a cross-section of output node (denoted as “OUT”) on the top transistor level, and a cross-section of output node (denoted as “OUT”) on the BEOL metal level illustrated in FIG. 16A.

FIG. 17A is a top view layout diagram of a NAND3 logic cell according to some embodiments of the present disclosure, wherein FIG. 17A illustrates a combined layout including a layout of top transistor level and a layout of bottom transistor level.

FIG. 17B is a cross-sectional view combining a cross-sectional cut B1-B1 on the top transistor level and a cross-sectional cut B2-B2 on the bottom transistor level illustrated in FIG. 17A.

FIG. 17C is a cross-sectional view combining a cross-sectional cut C1-C1 on the top transistor level and a cross-sectional cut C2-C2 on the bottom transistor level illustrated in FIG. 17A.

FIG. 17D is a cross-sectional view combining a cross-sectional cut D1-D1 on the top transistor level and a cross-sectional cut D2-D2 on the bottom transistor level illustrated in FIG. 17A.

FIG. 18A is a circuit diagram of a NAND logic gate.

FIG. 18B is a top view layout diagram of a NAND cell implemented using the DCH standard cell design in accordance with some embodiments of the present disclosure, wherein FIG. 18B illustrates a combined layout including a layout of top transistor level and a layout of bottom transistor level.

FIG. 18C is a cross-sectional view combining a cross-sectional cut C1-C1 on the top transistor level and a cross-sectional cut C2-C2 on the bottom transistor level illustrated in FIG. 18B.

FIG. 18D is a cross-sectional view combining a cross-sectional cut D1-D1 on the top transistor level and a cross-sectional cut D2-D2 on the bottom transistor level illustrated in FIG. 18B.

FIG. 19A is a circuit diagram of a NOR logic gate.

FIG. 19B is a top view layout diagram of a NOR cell implemented using the DCH standard cell design in accordance with some embodiments of the present disclosure, wherein FIG. 19B illustrates a combined layout including a layout of top transistor level and a layout of bottom transistor level.

FIG. 19C is a cross-sectional view combining a cross-sectional cut C1-C1 on the top transistor level and a cross-sectional cut C2-C2 on the bottom transistor level illustrated in FIG. 19B.

FIG. 19D is a cross-sectional view combining a cross-sectional cut D1-D1 on the top transistor level and a cross-sectional cut D2-D2 on the bottom transistor level illustrated in FIG. 19B.

FIG. 20A is a circuit diagram of an OAI21 logic gate.

FIG. 20B is a top view layout diagram of an OAI21 logic cell implemented using the DCH standard cell design in accordance with some embodiments of the present disclosure, wherein FIG. 20B illustrates a combined layout including a layout of top transistor level and a layout of bottom transistor level.

FIG. 20C is a cross-sectional view combining a cross-sectional cut C1-C1 on the top transistor level and a cross-sectional cut C2-C2 on the bottom transistor level illustrated in FIG. 20B.

FIG. 20D is a cross-sectional view combining a cross-sectional cut D1-D1 on the top transistor level and a cross-sectional cut D2-D2 on the bottom transistor level illustrated in FIG. 20B.

FIG. 20E is a cross-sectional view combining a cross-sectional cut E1-E1 on the top transistor level and a cross-sectional cut E2-E2 on the bottom transistor level illustrated in FIG. 20B.

FIG. 21A is a three-dimensional (3D) layout diagram of a NAND logic cell implemented using the DCH standard cell design in accordance with some embodiments of the present disclosure.

FIG. 21B is a top view layout of the NAND logic cell.

FIG. 21C is a cross-sectional view of a cross-sectional cut C-C illustrated in FIG. 21B.

FIG. 21D is a cross-sectional view of a cross-sectional cut D-D illustrated in FIG. 21B.

FIG. 21E is a cross-sectional view of a cross-sectional cut E-E illustrated in FIG. 21B.

FIG. 22A is a circuit diagram of a NAND4 logic gate.

FIG. 22B is a 3D layout diagram of a NAND4 cell implemented using the DCH standard cell design in accordance with some embodiments of the present disclosure.

FIG. 22C is a top view layout of the NAND4 cell, wherein FIG. 22C illustrates a combined layout including a layout of top transistor level and a layout of bottom transistor level.

FIG. 23A is a 3D layout diagram of a AOI21 cell implemented using the DCH standard cell design in accordance with some embodiments of the present disclosure.

FIG. 23B is a top view layout of the AOI21 cell, wherein FIG. 23B illustrates a combined layout including a layout of top transistor level and a layout of bottom transistor level.

FIG. 24A is a 3D layout diagram of a AOI22 cell implemented using the DCH standard cell design in accordance with some embodiments of the present disclosure.

FIG. 24B is a top view layout of the AOI22 cell, wherein FIG. 24B illustrates a combined layout including a layout of top transistor level and a layout of bottom transistor level.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly.

As the size of semiconductor devices become smaller, a cell height of standard cells also become smaller. The cell height is generally defined as a distance (pitch) between two power supply lines, VDD and VSS, and is generally determined by the number and a pitch of metal lines. The VDD supplied a higher potential than the VSS. The cell height can also be called a track height. Typical track heights may be 6 T (e.g., 6 tracks running over the standard cell) or 5 T (e.g., 5 tracks running over the standard cell). Scaling down to smaller track height is currently required to further minimize the size of semiconductor devices. To reduce the cell height, a complementary FET (CFET) in which a p-type FET and an n-type FET are vertically stacked has been proposed.

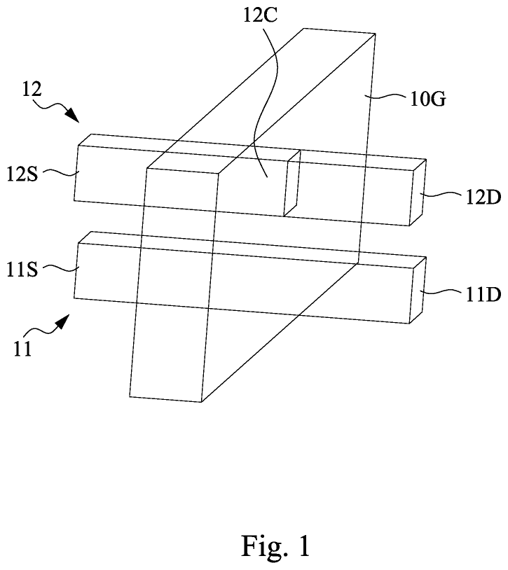

As shown in FIG. 1, in a CFET, a first gate-all-around field effect transistor (GAA FET) 11 is disposed over a substrate, and a second GAA FET 12 is disposed above the first GAA FET 11. The first GAA FET 11 includes a first source 11S and a first drain 11D, and the second GAA FET 12 includes a second source 12S and the second drain 12D. The source/drain of the first GAA FET is electrically separated from the source/drain of the second GAA FET in some embodiments. A gate structure 10G including a gate dielectric layer and a gate electrode layer is commonly formed around the channel regions 11C, 12C of the first and second GAA FETs 11, 12. In some embodiments, the first GAA FET 11 is a first conductivity type (e.g., n-type) FET and the second GAA FET 12 is a second conductivity type (e.g., p-type) different from the first conductivity type. In other embodiments, the first and second GAA FETs have the same conductivity type.

In some embodiments, the source of the second (upper) GAA FET 12 may be coupled to a first power supply line, e.g., Vdd, and the source of the first (bottom) GAA FET 11 is coupled to a second power supply line, e.g., Vss. In some embodiments, power supply lines are shared by adjacent cells.

Although the CFET scheme effectively reduces the footprint of a standard cell, the footprint reduction does not reduce the required interconnect for the standard cell. Therefore, the increased interconnect density may degrade CFET performance, such as routing congestion, resistive-capacitive (RC) delay, or even area. The present disclosure provides, in various embodiments, a standard cell having a double-cell-height (DCH) architecture in CFET design to achieve more flexibility for interconnect routing. A cell height of the DCH standard cell is twice a distance (pitch) between two power supply lines, V_{DD} and V_{SS}. The DCH standard cell includes two or more rows of transistors, transistor-level interconnects that provides metal routing in both the bottom transistor level (e.g., level at which the first GAA FET 11 is located) and the top transistor level (e.g., level at which the second GAA FET 12 is located), and inter-level source/drain via connecting source/drain regions of the top transistor and the bottom transistor. Because routing between rows of transistors can be implemented using the transistor-level interconnects formed in front-end-of-line (FEOL), the DCH standard cell can effectively reduce the interconnect length in back-end-of-line (BEOL) metal layers. Moreover, the interconnect complexity can be reduced because additional routing is available using the transistor-level interconnects, and thus the DCH standard cell can significantly mitigate routing congestion.

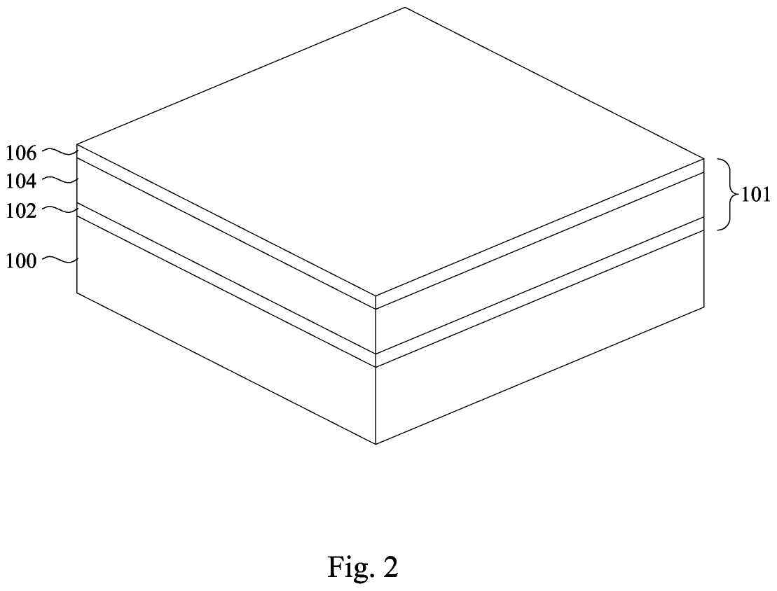

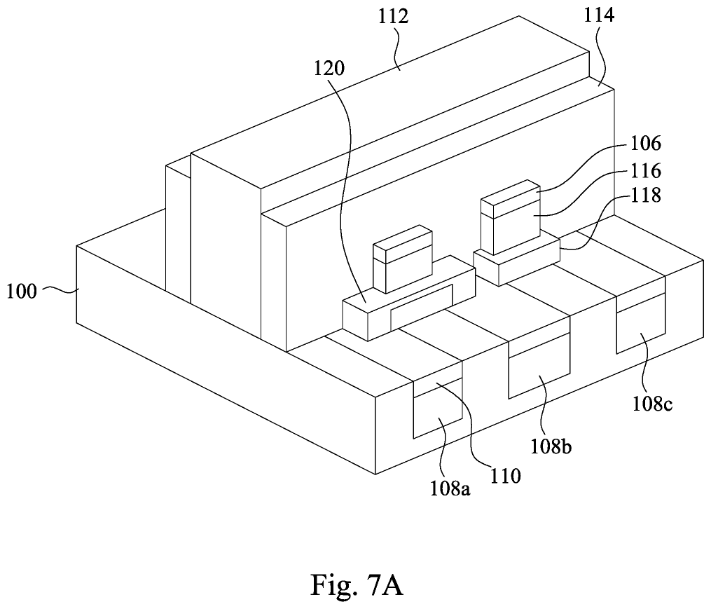

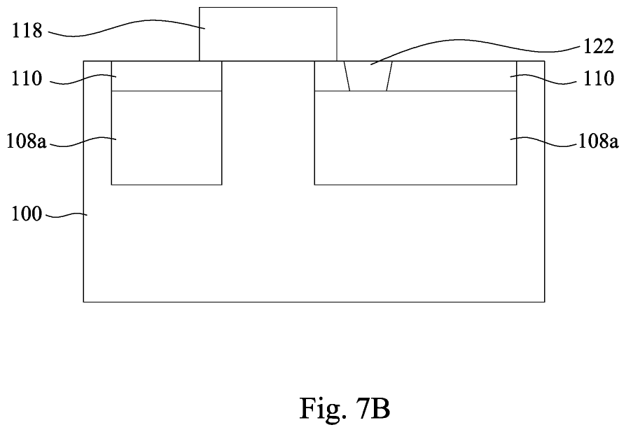

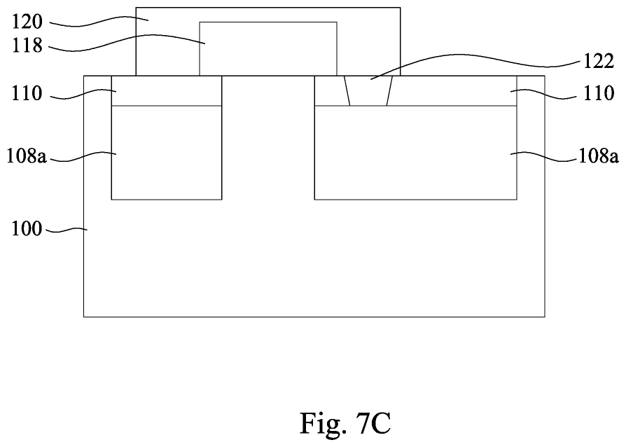

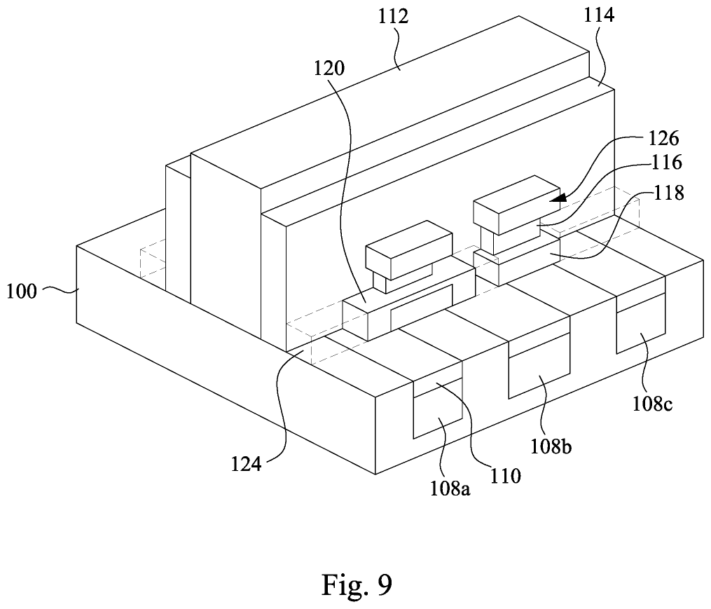

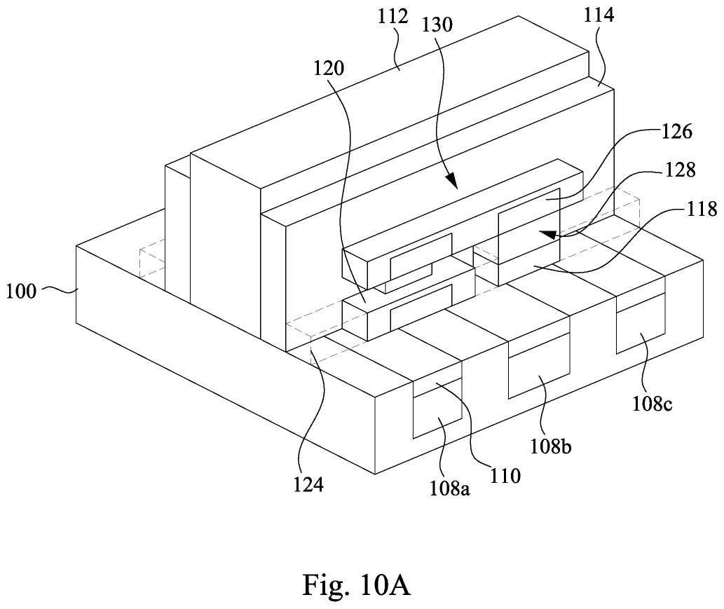

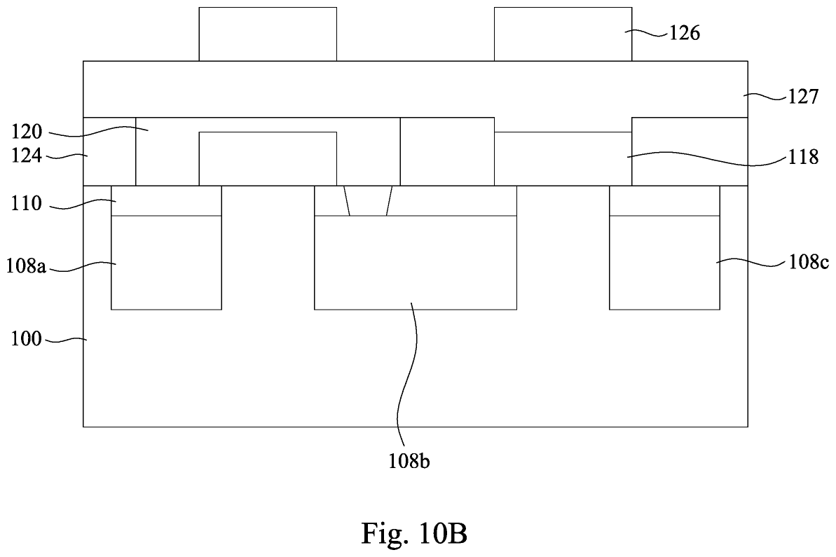

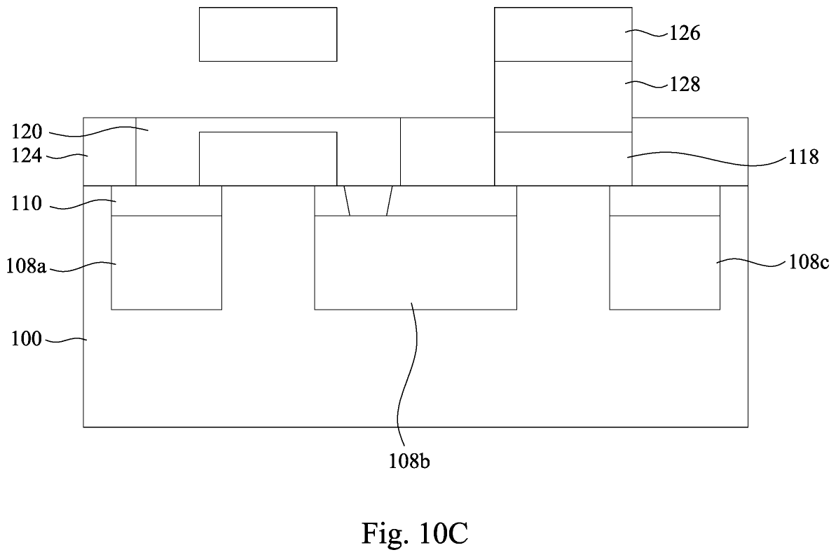

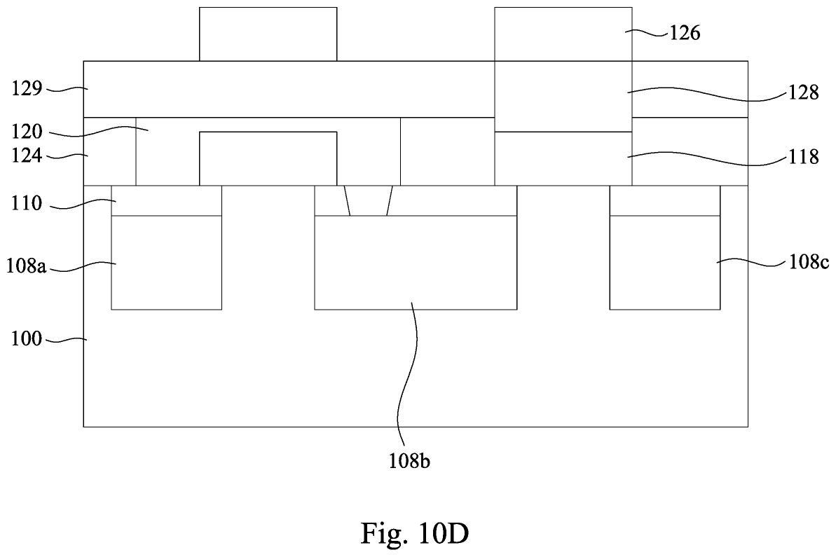

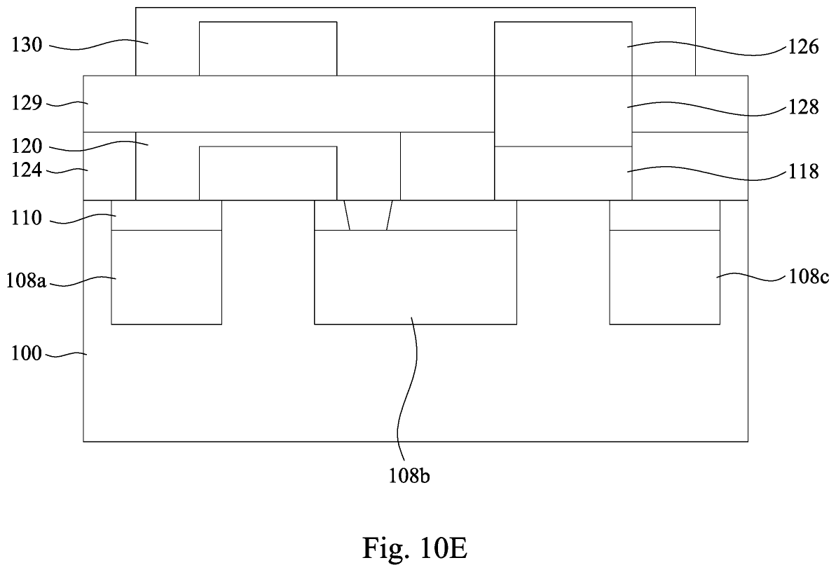

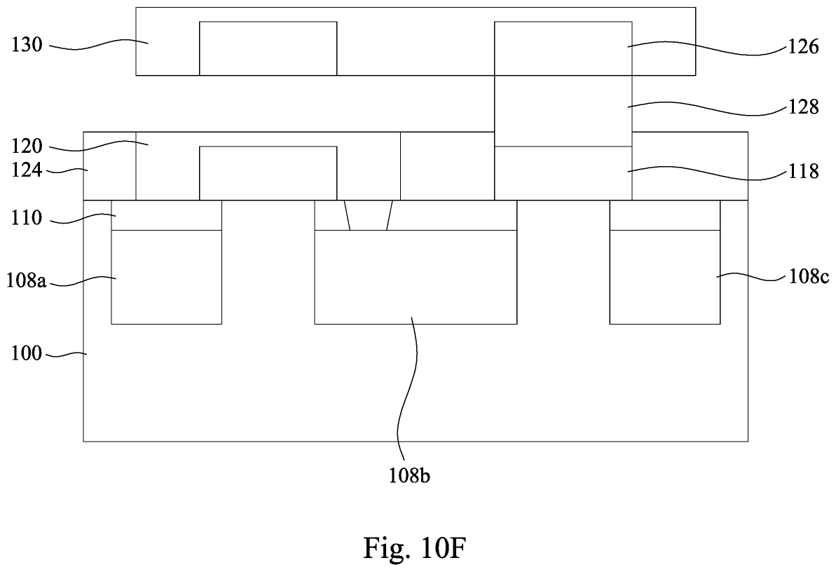

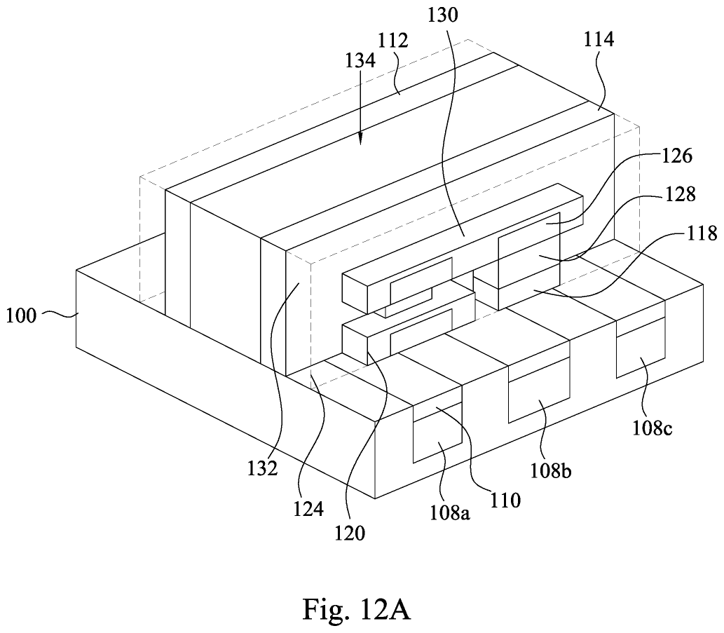

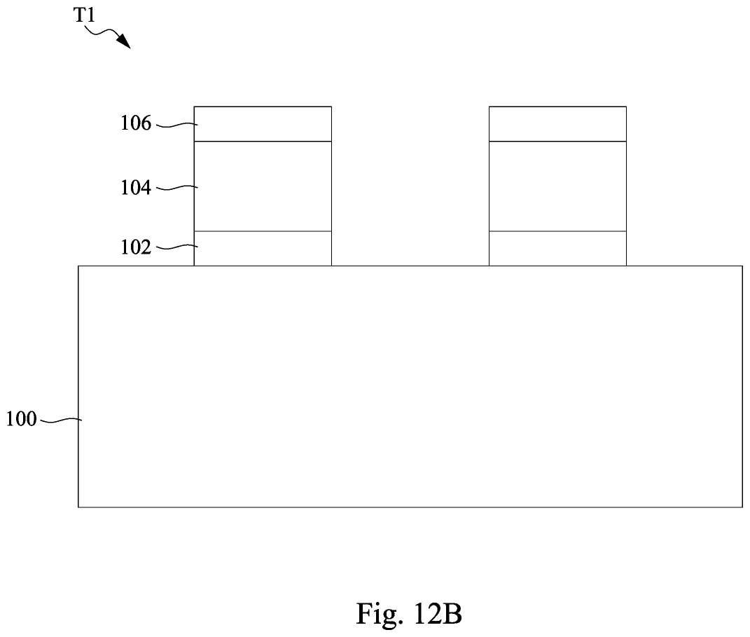

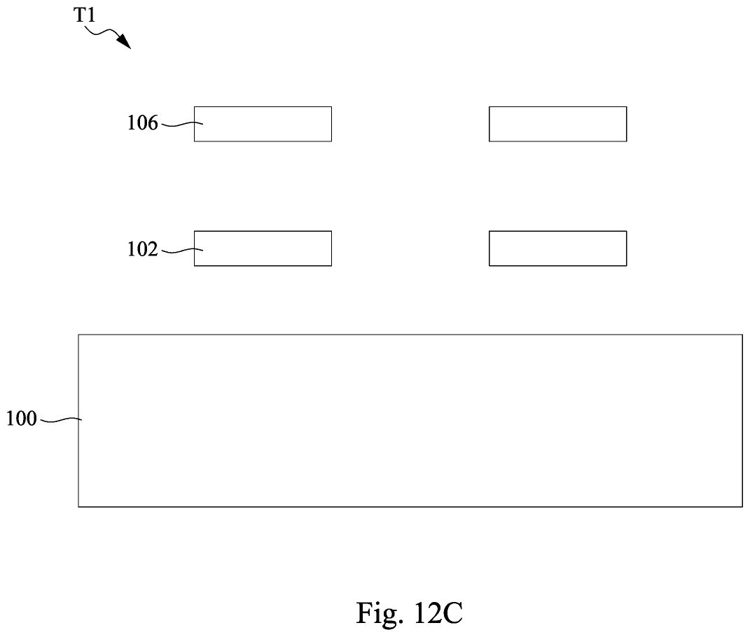

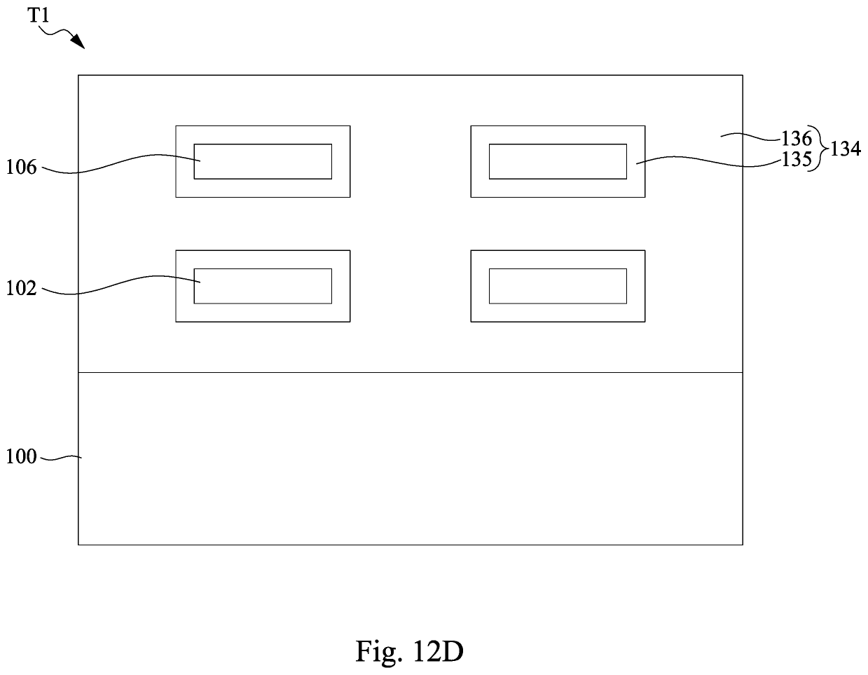

FIGS. 2 through 13 are perspective views and cross-sectional views of intermediate stages in manufacturing of a DCH CFET standard cell, in accordance with some embodiments, wherein FIGS. 2-7A, 8-10A, and 11-12A, and 13 are perspective views of intermediate stages in manufacturing of the DCH CFET standard cell, FIGS. 7B-7C are cross-sectional views of intermediate stages of example manufacturing processes illustrated in FIG. 7A, FIGS. 10B-10F are cross-sectional views of intermediate stages of example manufacturing processes illustrated in FIG. 10A, and FIGS. 12B-12D are cross-sectional views of intermediate stages of example manufacturing processes illustrated in FIG. 12A. Although the perspective views and cross-sectional views shown in FIGS. 2-13 are described with reference to a method, it will be appreciated that the structures shown in FIGS. 2-13 are not limited to the method but rather may stand alone separate of the method. Although FIGS. 2-13 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 2 is a perspective view of an example initial structure comprising a semiconductor substrate 100, a bottom semiconductor layer 102 formed over the semiconductor substrate 100, a sacrificial layer 104 formed over the bottom semiconductor layer 102, and a top semiconductor layer 106 formed over the sacrificial layer 104. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 101 is formed over the substrate 100. The multi-layer stack includes the bottom semiconductor layer 102, the top semiconductor layer 106, and the sacrificial layer 104 interposing the bottom semiconductor layer 102 and the top semiconductor layer 106. For purposes of illustration and as discussed in greater detail below, the sacrificial layer 104 will be removed, the bottom semiconductor layer 102 will be patterned to form channel regions of GAA FETs in a lower level, and the top semiconductor layer 106 will be patterned to form channel regions of GAA FETs in an upper level above the GAA FETs formed from the bottom semiconductor layer 102.

Each of the layers of the multi-layer stack 101 may be epitaxially grown using a process such as chemical vapor deposition (CVD), atomic layer deposition (ALD), vapor phase epitaxy (VPE), molecular beam epitaxy (MBE), or the like. In various embodiments, the bottom semiconductor layer 102 and the top semiconductor layer 106 may be formed of a semiconductor material suitable for serving as channel regions of GAA FETs, such as silicon, silicon carbon, silicon germanium, or the like. In some embodiments, the bottom semiconductor layer 102 and the top semiconductor layer 106 may be formed of different semiconductor materials. For example, the bottom semiconductor layer 102 may be formed of silicon carbon, and the top semiconductor layer 106 may be formed of silicon germanium. The sacrificial layer 104 may be materials having a high-etch selectivity to the semiconductor layers 102 and 106. As such, the sacrificial layer 104 may be removed without significantly removing the semiconductor layers 102 and 106, thereby allowing the semiconductor layers 102 and 106 to serve as channel regions of GAA FETs.

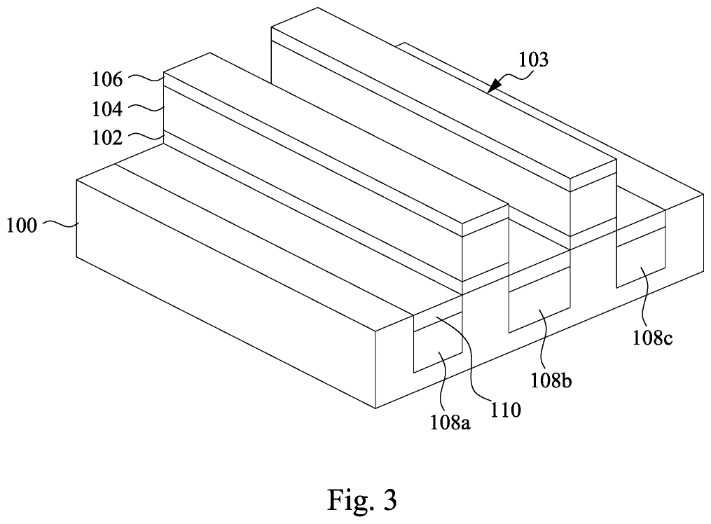

In FIG. 3, the multi-layer stack 101 is patterned to form fin structures 103 by using suitable photolithography and etching techniques. The etching may be any acceptable etch process, such as a reactive ion etch (RIE), neutral beam etch (NBE), the like, or a combination thereof. The etching may be anisotropic. The fin structure 103 each including portions of bottom semiconductor layer 102, sacrificial layer 104, and top semiconductor layer 106. In FIG. 3, two fin structures 130 are formed, and thus two rows of transistors will be formed in subsequent steps.

The fin structures 103 may be patterned by any suitable method. For example, the fin structures 103 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 103.

After forming the fin structures 103, power supply lines 108a, 108b and 108c (collectively referred to as power supply lines 108) are formed in the semiconductor substrate 100. Because these power supply lines 108 are inlaid in the substrate 100, they are also called buried power rails (BPRs). In some embodiments, the BPR 108a and 108c are V_{DD} (e.g., positive potential) lines, and the BPR 108b is a V_{SS} (e.g., negative or ground potential) line. The BPRs 108 may include one or more layers of Co, Ni, W, Ti, Ta, Cu, Al, TiN and TaN, or any other suitable conductive material.

The BPRs 108 can be formed by, for example, etching trenches in exposed regions of the substrate 100 not covered by the fin structures 103, depositing one or more metals in the trenches, selectively etching back the one or more metals until tops of the one or more metals fall below a top surface of the semiconductor substrate 100, while leaving portions of the one or more metals in the trenches to serve as BPRs 108. Then, capping layers 110 are formed to cap the top surfaces of the BPRs 108 by using, for example, depositing a dielectric material (e.g., silicon oxide or silicon nitride) in the trenches and over the BPRs 108, and then selectively etching back the dielectric material until a top of the dielectric material falls below the top surface of the semiconductor substrate 100, while leaving portions of the dielectric material in the trenches to serve as capping layers 110.

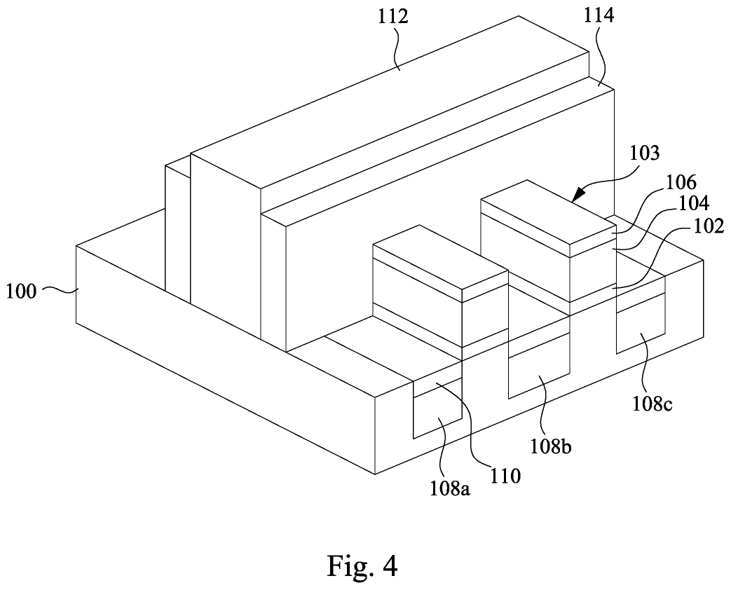

In FIG. 4, a dummy gate structure 112 is formed across the fin structures 103. In some embodiments, the dummy gate structure 112 may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric. A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure 112 may extend along multiple sides of the fin structures 130 and extend between the fin structures 103 over the capping layer 110. As described in greater detail below, the dummy gate structure 112 may be replaced by a replacement gate structure in a subsequent step. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

After forming the dummy gate structure 112, gate spacers 114 are formed, for example, self-aligned to the dummy gate structure 112. The gate pacers 114 may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structure 112 leaving the gate spacers 114 along the sidewalls of the dummy gate structure 112.

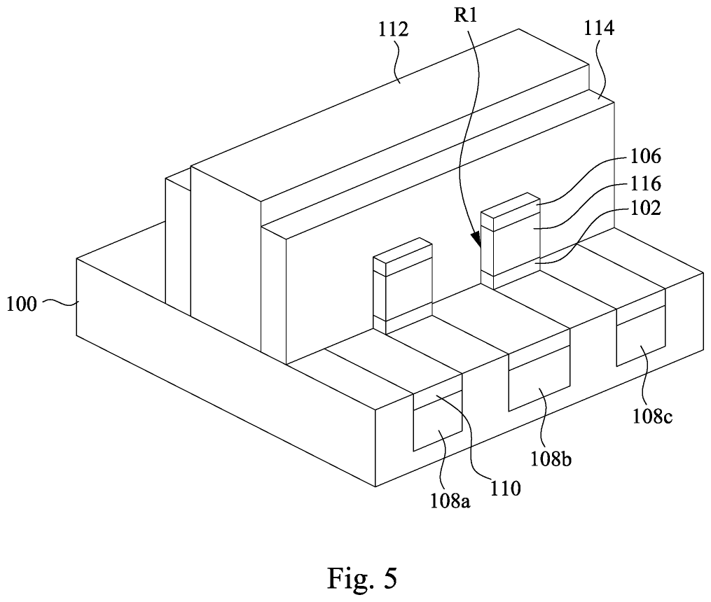

In FIG. 5, portions of the fin structures 103 expend beyond the gate spacers 114 and the dummy gate structure 112 are removed by using suitable photolithography and etching techniques. Next, the sacrificial layers 104 in the fin structures 103 are laterally recessed by using selective etching, thus forming recesses R1 between bottom semiconductor layer 102 and top semiconductor layer 106 in each fin structure 103. Inner spacers 116 are then formed in the recesses R1 by using, for example, depositing a dielectric material over the substrate 100, followed by anisotropically etching the dielectric material to remove portions of the dielectric material outside the recesses R1, while leaving portions of the dielectric material in the recesses R1 to serve as inner spacers 116. In some embodiments, the inner spacers 116 may comprise a dielectric material such as silicon nitride or silicon oxynitride, although any suitable material, such as low-dielectric constant (low-k) materials having a k-value less than about 3.5, may be utilized.

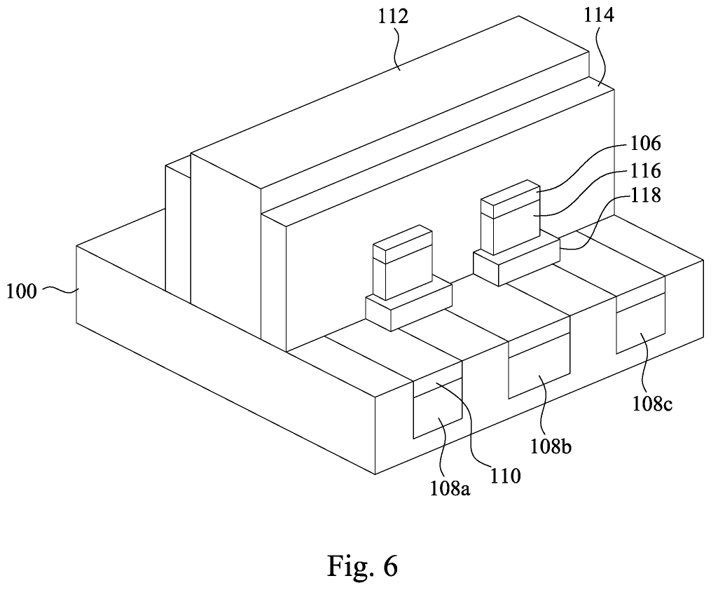

In FIG. 6, bottom source/drain regions 118 are epitaxially grown from the bottom semiconductor layer 102. In some embodiments, the bottom source/drain regions 118 may exert stress on the bottom semiconductor layer 102, thereby improving device performance. The dummy gate structure 112 is disposed between respective neighboring pairs of the epitaxial source/drain regions 118. In some embodiments, the gate spacers 114 are used to separate the epitaxial source/drain regions 118 from the dummy gate structure 112, so that the epitaxial source/drain regions 118 do not short out with subsequently formed gates of the resulting GAA FETs. The bottom source/drain regions 118 may be formed using a selective epitaxy growth (SEG) process. In some embodiments, some epitaxial materials may be unintentionally grown on the top semiconductor layer 106. In that case, these epitaxial materials can be removed from the top semiconductor layer 106 by using, for example, an angled etching process that etches the epitaxial materials on the top semiconductor layer 106, while leaving epitaxial material on the bottom semiconductor layer 102 due to shadowing effect resulting from a tilting angle of ion beams used in the angled etching process.

In some embodiments where the bottom-transistors are n-type GAA FETs, the epitaxial source/drain regions 118 may include any acceptable material appropriate for n-type GAA FETs. For example, if the bottom semiconductor layer 102 is silicon, the bottom source/drain regions 118 may include materials exerting a tensile strain on the bottom semiconductor layer 102, such as silicon carbide, phosphorous doped silicon carbide, silicon phosphide, or the like. In some embodiments where the bottom- transistors are p-type GAA FETs, the bottom source/drain regions 118 may include any acceptable material appropriate for p-type GAA FETs. For example, if the bottom semiconductor layer 102 are silicon, the bottom source/drain regions 118 may comprise materials exerting a compressive strain on the bottom semiconductor layer 102, such as silicon germanium, boron doped silicon germanium, germanium, germanium tin, or the like. The bottom source/drain regions 118 may be implanted with n-type dopants or p-type dopants to form source/drain regions, followed by an anneal. In some embodiments, the bottom source/drain regions 118 may be in situ doped during growth.

In FIG. 7A, bottom-transistor-level interconnects (e.g., a bottom-transistor-level metal line 120) are formed at a same level as the bottom source/drain regions 118. The bottom-transistor-level interconnects allow for metal routing at the bottom transistor level, which in turn will alleviate routing congestion in BEOL metal layers. The bottom-transistor-level interconnects may include row-to-row interconnects and/or transistor-to-power-rail interconnects. In some embodiments where the bottom-transistor-level interconnect is a row-to-row interconnect, it is a metal line extending from a bottom source/drain region 118 in one row to a bottom source/drain region 118 in next row. In some embodiments where the bottom-transistor-level interconnect is a transistor-to-power-rail interconnect, it is a metal line extending from a bottom source/drain region 118 to a position directly above a target power rail. For example, the bottom-transistor-level metal line 120 may be a transistor-to-power-rail interconnect that electrically connecting a source/drain region 118 to the BPR 108b. In that case, a via may be formed in the capping layer 110 to electrically connecting the bottom-transistor-level metal line 120 to the BPR 108b.

FIGS. 7B-7C illustrate cross-sectional views of an example method of forming the transistor-to-power-rail interconnect. In FIG. 7B, a backside via 122 is formed extending through the capping layer 110 to the BPR 108b by using, form example, etching a via opening in the capping layer 110 and then filling the via opening with the backside via 122 by depositing a metal material in the via opening and then selectively etching back the metal material. In FIG. 7C, a bottom-transistor-level metal line 120 is formed across the source/drain region 118 to directly above the backside via 122 by using, for example, depositing a metal material over the substrate 110, selectively etching back the metal material until a top surface of metal material is below the top semiconductor layer 106, followed by patterning the metal material into the bottom-transistor-level interconnects which includes the bottom-transistor-level metal line 120.

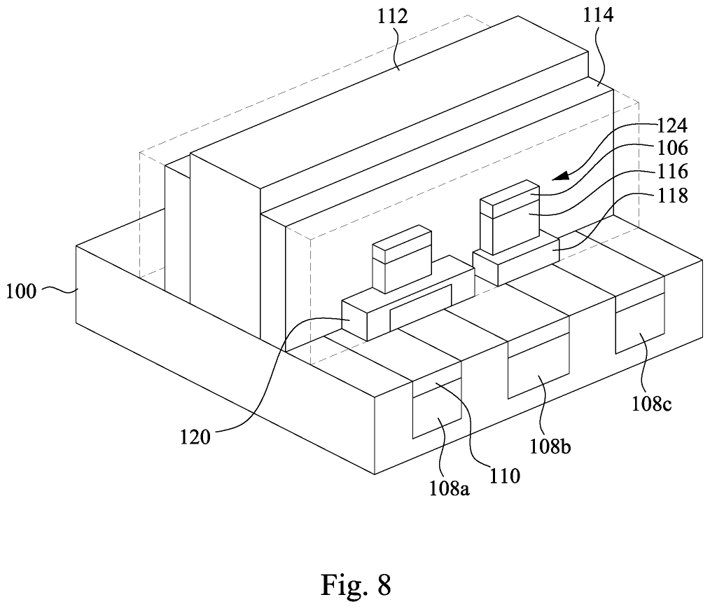

In FIG. 8, a passivation layer 124 is formed over the substrate 100. The passivation layer 124 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the passivation layer 124 may be patterned.

In FIG. 9, the passivation layer 124 is etched back until a top surface of the passivation layer falls below the top semiconductor layer 106, and then top source/drain regions 126 are epitaxially grown from exposed regions of the top semiconductor layer 106. In some embodiments, the top source/drain regions 126 may exert stress on the top semiconductor layer 106, thereby improving device performance. The dummy gate structure 112 is disposed between respective neighboring pairs of the top source/drain regions 126. In some embodiments, the gate spacers 114 are used to separate the top source/drain regions 126 from the dummy gate structure 112, so that the epitaxial source/drain regions 126 do not short out with subsequently formed gates of the resulting GAA FETs. The top source/drain regions 126 may be formed using a selective epitaxy growth (SEG) process.

In some embodiments where the top-transistors are p-type GAA FETs, the top source/drain regions 126 may include any acceptable material appropriate for p-type GAA FETs. For example, if the top semiconductor layer 106 are silicon, the top source/drain regions 126 may comprise materials exerting a compressive strain on the top semiconductor layer 106, such as silicon germanium, boron doped silicon germanium, germanium, germanium tin, or the like. In some embodiments where the top transistors are n-type GAA FETs, the top source/drain regions 126 may include any acceptable material appropriate for n-type GAA FETs. For example, if the top semiconductor layer 106 is silicon, the top source/drain regions 126 may include materials exerting a tensile strain on the top semiconductor layer 106, such as silicon carbide, phosphorous doped silicon carbide, silicon phosphide, or the like. The top source/drain regions 126 may be implanted with p-type dopants or n-type dopants to form source/drain regions, followed by an anneal. In some embodiments, the top source/drain regions 126 may be in situ doped during growth.

In FIG. 10A, an inter-level source/drain via 128 is formed between the bottom source/drain region 118 and the top source/drain region 126, and thus electrically connecting the bottom source/drain region 118 and the top source/drain region 126. The inter-level source/drain via 128 can be interchangeably referred to as a common source/drain via shared by the bottom source/drain region 118 and the top source/drain region 126. FIG. 10A further illustrates top-transistor-level interconnects (e.g., a top-transistor-level metal line 130) formed at a same level as the top source/drain regions 126. The top-transistor-level interconnects allow for metal routing at the top transistor level, which in turn will alleviate routing congestion in BEOL metal layers. The top-transistor-level interconnects may include row-to-row interconnects and/or transistor-to-power-rail interconnects. In some embodiments where the top-transistor-level interconnect is a transistor-to-power-rail interconnect, it is a metal line extending from a top source/drain region 126 to a position directly above a target power rail. In some embodiments where the top-transistor-level interconnect is a row-to-row interconnect, it is a metal line 130 extending from a top source/drain region 126 in one row to a top source/drain region 126 in next row.

FIGS. 10B-10F illustrate cross-sectional views of an example method of forming the inter-level via and the top-transistor-level interconnects. In FIG. 10B, after etching back the passivation layer 124, a metal layer 127 is formed over the etched back passivation layer 124. The metal layer 127 is then selectively etched back to below the top source/drain regions 126. Next, the meal layer 127 is patterned into the inter-layer source/drain via 128 using suitable photolithography and etching techniques. The resulting structure is illustrated in FIG. 10C. Then, in FIG. 10D, a sacrificial layer 129 is deposited over the substrate 100 and then etched back to below the top source/drain regions 126. Next, top-transistor-level interconnects (e.g., top-transistor-level metal line 130) are formed over the sacrificial layer 129 by using, for example, depositing a metal material over the sacrificial layer 129, followed by patterning the metal material into the top-transistor-level interconnects. The sacrificial layer 129 is then removed, as illustrated in FIG. 10F.

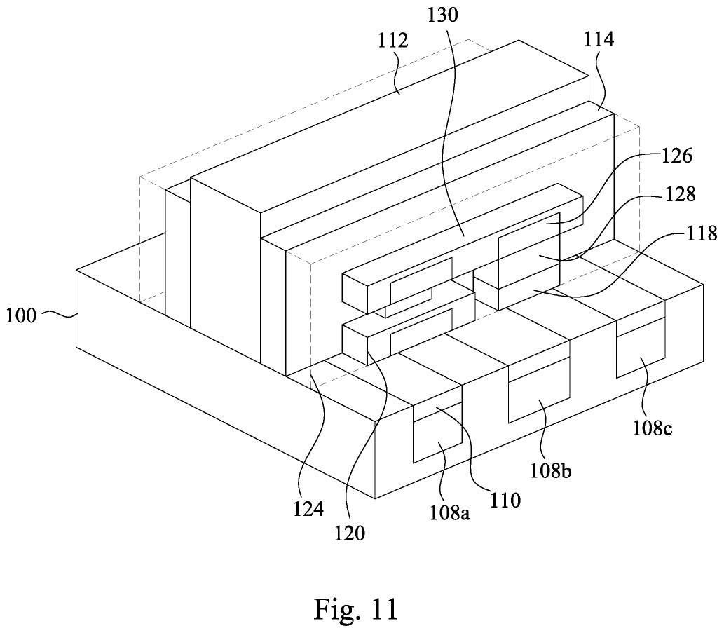

In FIG. 11, another passivation layer 132 is deposited over the top-transistor-level interconnects, and then etched back to below a top surface of the dummy gate structure 112.

In FIG. 12A, the dummy gate structure 112 is replaced with a replacement metal gate structure 134. FIGS. 12B-12D illustrate cross-sectional views in the gate region showing an example method of the gate replacement process illustrated in FIG. 12A. In FIG. 12B, the dummy gate structure 112 is removed by using a selective etching process to form a gate trench T1 between the gate spacers 114. In FIG. 12C, the sacrificial layers 104 in the gate trench T1 are removed by another selective etching process that etches the sacrificial layers 104 at a faster etch rate than etching the bottom, top semiconductor layers 102, 106 and the substrate 100. In some embodiments, the selective etching process may also remove some portions of the bottom semiconductor layer 102 and/or the substrate 100, such that the bottom semiconductor layer 102 is spaced apart from the substrate 100. This step can be referred to as a channel release process. At this interim processing step, the spaces between bottom and top semiconductor layers 102, 106 may be filled with ambient environment conditions (e.g., air, nitrogen, etc.). In some embodiments, the bottom and top semiconductor layers 102, 106 can be referred to as semiconductor nanostructures such as nanosheets, nanowires, nanoslabs, nanorings having nano-scale size (e.g., a few nanometers), depending on their geometry. For example, in some embodiments the bottom and top semiconductor layers 102, 106 may be trimmed to have a substantial rounded shape (i.e., cylindrical) due to the selective etching process for completely removing the sacrificial layers 104. In that case, the resultant bottom semiconductor layers 102, 106 can be called semiconductor nanowires.

In FIG. 12D, the replacement gate structure 134 is formed in the gate trench T1 to surround each of the semiconductor layers 102, 106 suspended in the gate trench T1. The gate structures 134 may be final gates of GAA FETs. The final gate structure may be a high-k/metal gate stack, however other compositions are possible. In some embodiments, each of the gate structures 134 forms the gate associated with the multi-channels provided by the plurality of semiconductor layers 102, 106. In various embodiments, the gate structure 134 includes a gate dielectric layer 135 formed around the semiconductor layers 102, 106, and a gate metal layer 136 formed around the gate dielectric layer 135. Formation of the gate structures 134 may include one or more deposition processes to form various gate materials, followed by a CMP process to remove excessive gate materials, resulting in the gate structures 134 remaining in the gate trench T1.

In some embodiments, the gate dielectric layer 135 may include an interfacial layer (e.g., silicon oxide) formed around the semiconductor layers 102, 106, and a high-k gate dielectric layer formed over the interfacial layer. The high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof. The gate metal layer 136 is formed on the gate dielectric layer 134 to surround each channel layer. The gate metal layer 136 includes one or more layers of metal material, such as titanium, tantalum, tungsten, cobalt, molybdenum, tantalum nitride, nickel silicide, aluminum, copper, cobalt silicide, TiN, WN, TiAl, TiAlN, TaCN, TaC, TaSiN, metal alloys, other suitable materials, and/or combinations thereof. The gate metal layer 136 may be formed by CVD, ALD, electro-plating, or other suitable method.

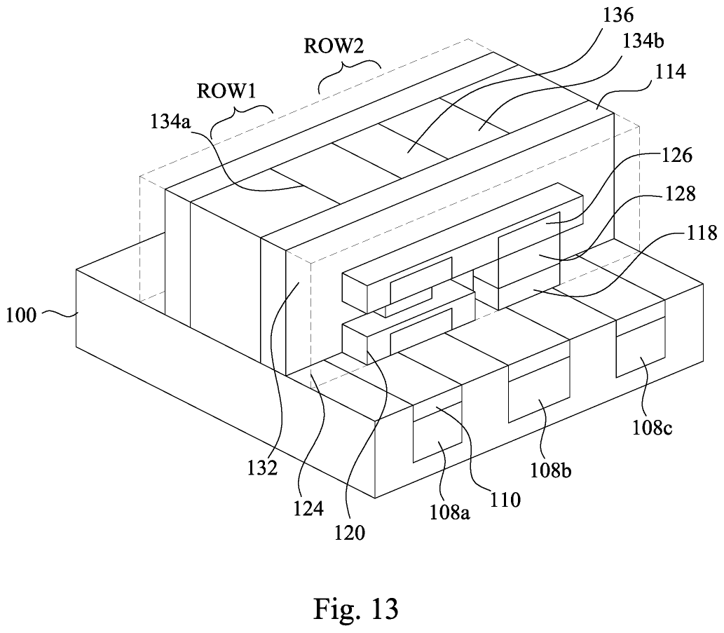

In FIG. 13, an etching process is performed to break the single continuous gate structure 134 into separate gate structures 134a and 134b, and then an isolation structure 136 is formed between the gate structures 134a and 134b by suitable deposition techniques. This step is also called a gate cut step. The resultant structure includes two rows of transistors. In particular, transistors in the first row ROW1 includes a bottom transistor (e.g., NFET) and a top transistor (e.g., PFET) sharing a same gate structure 134a, and transistors in the second row ROW2 includes a bottom transistor (e.g., NFET) and a top transistor (e.g., PFET) sharing a same gate structure 134b.

A source/drain region of the bottom transistor in the first row ROW1 can be electrically coupled to a source/drain region of the bottom transistor in the second row ROW2 by using bottom-transistor-level interconnects (e.g., bottom-transistor-level metal line 120). A source/drain region of the top transistor in the first row ROW1 can be electrically coupled to a source/drain region of the top transistor in the second row ROW2 by using top-transistor-level interconnects (e.g., top-transistor-level metal line 130). A source/drain region of the top transistor in the second row ROW2 can be electrically coupled to a source/drain region of the bottom transistor in in the second row ROW2 by using an inter-level via (e.g., via). As a result, the bottom-transistor-level interconnects, top-transistor-level interconnects, and the inter-level via can provide routing for CFETs in adjacent rows without using BEOL metal layers, which in turn will alleviate routing congestion in BEOL metal layers. Therefore, various standard cells can be developed by using the bottom-transistor-level interconnects, top-transistor-level interconnects, and the inter-level via, as discussed in detail below.

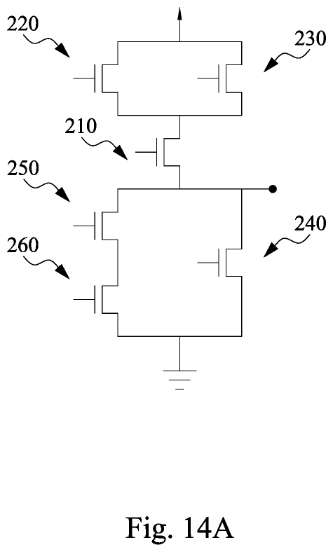

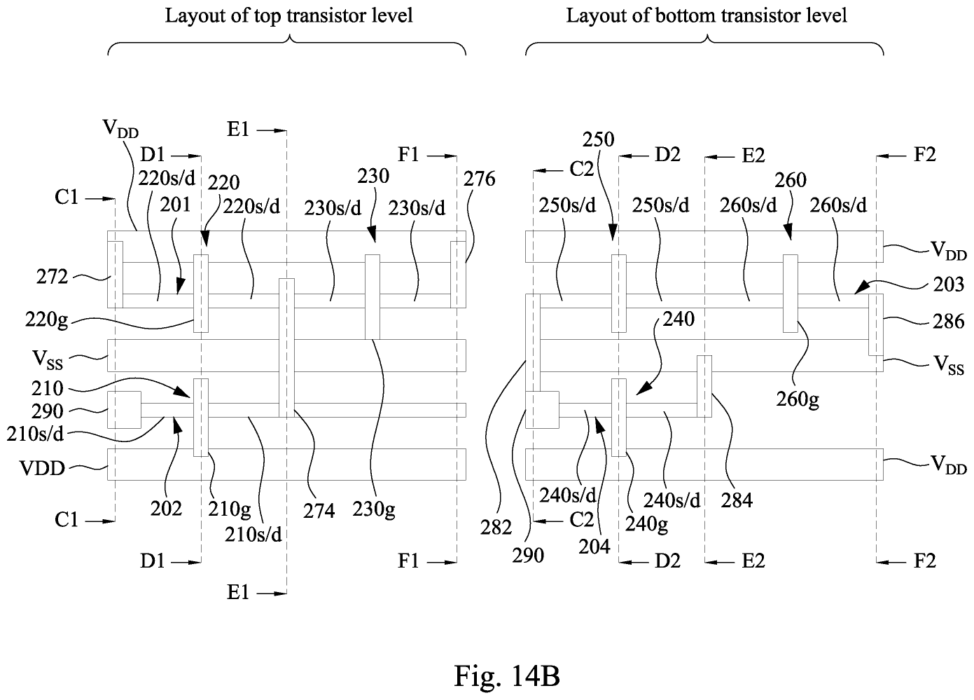

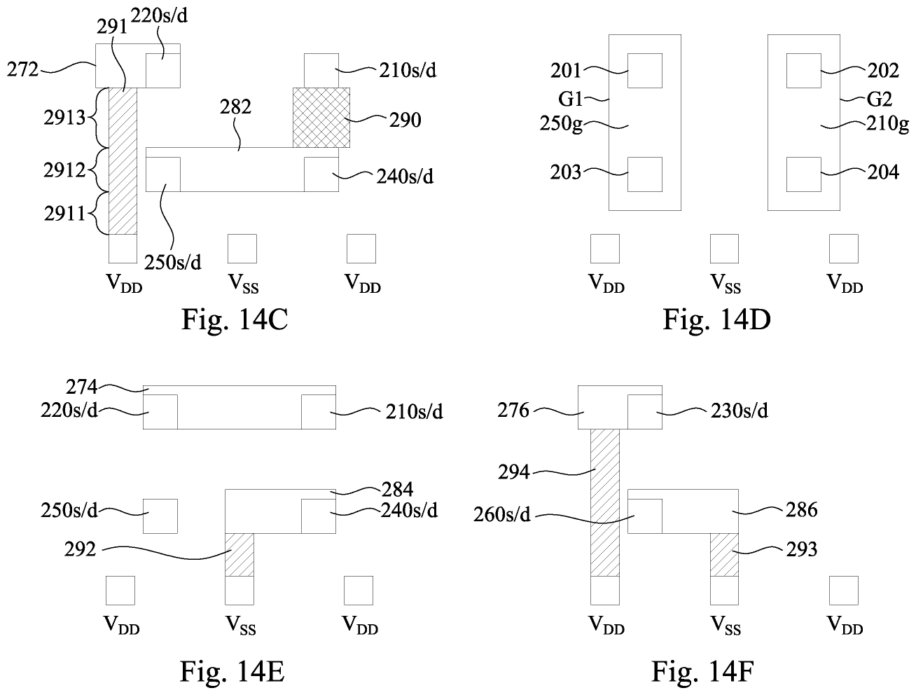

FIG. 14A is a circuit diagram of a AND-OR-invert (AOI) 21 logic gate (also called AOI21 logic gate). FIG. 14B is a top view layout diagram of an AOI21 logic cell implemented using the DCH standard cell design in accordance with some embodiments of the present disclosure, wherein FIG. 14B illustrates a combined layout including a layout of top transistor level and a layout of bottom transistor level. FIG. 14C is a cross-sectional view combining a cross-sectional cut C1-C1 on the top transistor level and a cross-sectional cut C2-C2 on the bottom transistor level illustrated in FIG. 14B. FIG. 14D is a cross-sectional view combining a cross-sectional cut D1-D1 on the top transistor level and a cross-sectional cut D2-D2 on the bottom transistor level illustrated in FIG. 14B. FIG. 14E is a cross-sectional view combining a cross-sectional cut E1-E1 on the top transistor level and a cross-sectional cut E2-E2 on the bottom transistor level illustrated in FIG. 14B. FIG. 14F is a cross-sectional view combining a cross-sectional cut F1-F1 on the top transistor level and a cross-sectional cut F2-F2 on the bottom transistor level illustrated in FIG. 14B.

As illustrated in FIG. 14B, the AOI21 logic cell is a DCH cell having a cell height that is twice the pitch between two power supply lines, V_{DD} and V_{SS}. The DCH cell includes two rows of CFETs. The upper row of CFETs is formed using a top semiconductor layer 201 as PFET channels and using a bottom semiconductor layer 203 as NFET channels, and the lower row of CFETs is formed using a top semiconductor layer 202 as PFET channels and using a bottom semiconductor layer 204 as NFET channels.

The AOI21 logic cell includes top transistors (p-type transistors) 210, 220, 230, and bottom transistors (n-type transistors) 240, 250, and 260 disposed below the top transistors 210, 220, and 230, respectively. The p-type transistors 220 and 230 are arranged in an upper row, and the n-type transistors 250 and 260 are arranged in the upper row and vertically stacked below the p-type transistors 220 and 230. The p-type transistor 210 are arranged in a lower row, and the n-type transistor 240 is arranged in the lower row and vertically stacked below the p-type transistor 210.

The p-type transistor 210 includes a gate 210g, and p-type source/drain regions 210s/d on opposite sides of the gate 210g. The p-type transistor 220 includes a gate 220g, and p-type source/drain regions 220s/d on opposite sides of the gate 220g. The p-type transistor 230 includes a gate 230g, and p-type source/drain regions 230s/d on opposite sides of the gate 230g. The n-type transistor 240 is disposed directly below the p-type transistor 210 and includes a gate 240g, and n-type source/drain regions 240s/d on opposite sides of the gate 240g. The n-type transistor 250 is disposed directly below the p-type transistor 220 and includes a gate 250g, and n-type source/drain regions 250s/d on opposite sides of the gate 250g. The n-type transistor 260 is disposed directly below the p-type transistor 230 and includes a gate 260g, and n-type source/drain regions 260s/d on opposite sides of the gate 260g.

First one of the source/drain regions 220s/d of the p-type transistor 220 is electrically coupled to V_{DD} line by using a top-transistor-level metal line 272, and second one of the source/drain regions 220s/d of the p-type transistor 220 is electrically coupled to a first one of the source/drain regions 210s/d of the p-type transistor 210 in next row by using a top-transistor-level metal line 274. A second one of the source/drain regions 210s/d of the p-type transistor 210 is electrically coupled to a first one of the source/drain regions 240s/d of the n-type transistor 240 by using an inter-level source/drain via 290. A first one of the source/drain regions 230s/d of the p-type transistor 230 and the second one of the source/drain regions 220s/d of the p-type transistor 220 are a shared source/drain region (e.g., a same epitaxial region shared by two adjacent gates), and they are electrically coupled to the first one of the source/drain regions 210s/d of the p-type transistor 210 in next row by using the top-transistor-level metal line 274. A second one of the source/drain regions 230s/d of the p-type transistor 230 is electrically coupled to V_{DD} line by using a top-transistor-level metal line 276.

The first one of the source/drain regions 240s/d of the n-type transistor 240 is electrically coupled to a first one of source/drain regions 250s/d of the n-type transistor 250 by using a bottom-transistor-level metal line 282. A second one of source/drain regions 240s/d is electrically coupled to V_{SS} line by using a bottom-transistor-level metal line 284. A first one of source/drain regions 260s/d of the n-type transistor 260 is electrically coupled to V_{SS} line by using a bottom-transistor-level metal line 286. A second one of source/drain regions 260s/d of the n-type transistor 260 and a second one of source/drain regions 250s/d of the n-type transistor 250 are a shared source/drain region.

In FIG. 14C, the inter-level source/drain via 290 extending upwards from the n-type source/drain region 240s/d to the p-type source/drain region 210s/d. The inter-level source/drain via 290 can be manufactured using the process steps and materials of forming the inter-level source/drain via 128 as discussed previously with respect to FIGS. 10A-10F. The n-type source/drain regions may be epitaxial regions formed using the process steps and materials of forming the bottom source/drain regions 118 as discussed previously with respect to FIG. 6. The p-type source/drain regions may be epitaxial regions formed using the process steps and materials of forming the top source/drain regions 126 as discussed previously with respect to FIG. 9.

In FIG. 14C, the bottom-transistor-level metal line 282 extends laterally between source/drain regions 240s/d and 250s/d in adjacent rows. In FIG. 14E, the bottom-transistor-level metal line 284 extends laterally from the source/drain region 240s/d to a position directly above the V_{SS} line, and a backside via 292 vertically extends from the bottom-transistor-level metal line 284 to the V_{SS} line. In FIG. 14F, the bottom-transistor-level metal line 286 extends laterally from the source/drain region 260s/d to a position directly above the V_{SS} line, and a backside via 293 vertically extends from the bottom-transistor-level metal line 286 to the V_{SS} line. The bottom-transistor-level metal lines 282, 284, and 286 can be manufactured using the process steps and materials of forming the bottom-transistor-level metal line 120 as discussed previously with respect to FIGS. 7A-7C. The backside vias 292 and 293 can be manufactured using the process steps and materials of forming the backside via 122 as discussed previously with respect to FIGS. 7A-7C.

In FIG. 14C, the top-transistor-level metal line 272 extends laterally from the source/drain region 220s/d to a position directly above the V_{DD} line, and a via 291 vertically extends from the top-transistor-level metal line 272 to the V_{DD} line. In FIG. 14E, top-transistor-level metal line 274 laterally extends between source/drain regions 210s/d and 220s/d in adjacent rows. In FIG. 14F, the top-transistor-level metal line 276 laterally extends from the source/drain region 230s/d to a position directly above the V_{DD} line, and a via 294 vertically extends from the top-transistor-level metal line 276 to the V_{DD} line. In some embodiments, the top-transistor-level metal lines 272, 274 and 274 can be manufactured using the process steps and materials of forming the top-transistor-level metal line 130 as discussed previously with respect to FIGS. 10A-10F. The via 291 includes a first section 2911, a second section 2912 above the first section 2911, and a third section 2913 above the second section 2912. The first section 2911 may be formed simultaneously with forming the backside vias 292, 293. The second section 2912 may be formed simultaneously with forming the bottom-transistor-level metal liens. The third section 2913 may be formed simultaneously with forming the inter-level via 290. The via 294 connecting the top-transistor-level metal line 276 and the V_{DD} line can be formed in the same manner as forming the via 291.

In FIG. 14D, in some embodiments, the PFET gate 220g and the NFET gate 250g share a same gate structure G1 that surrounds a p-channel in the top semiconductor layer 201 and an n-channel in the bottom semiconductor layer 204. Similarly, the PFET gate 210g and the NFET gate 240g share a same gate structure that surrounds a p-channel in the top semiconductor layer 201 and an n-channel in the bottom semiconductor layer 204. In some embodiments, an upper portion of the gate structure G1 constituting the PFET gate 220g is formed of a same material as a lower portion of the gate structure G1 constituting the NFET gate 250g. In some embodiments, an upper portion of the gate structure G1 constituting the PFET gate 220g is formed of a different material than a lower portion of the gate structure G1 constituting the NFET gate 250g. In some embodiments, an upper portion of the gate structure G2 constituting the PFET gate 210g is formed of a same material as a lower portion of the gate structure G1 constituting the NFET gate 240g. In some embodiments, an upper portion of the gate structure G1 constituting the PFET gate 210g is formed of a different material than a lower portion of the gate structure G1 constituting the NFET gate 240g.

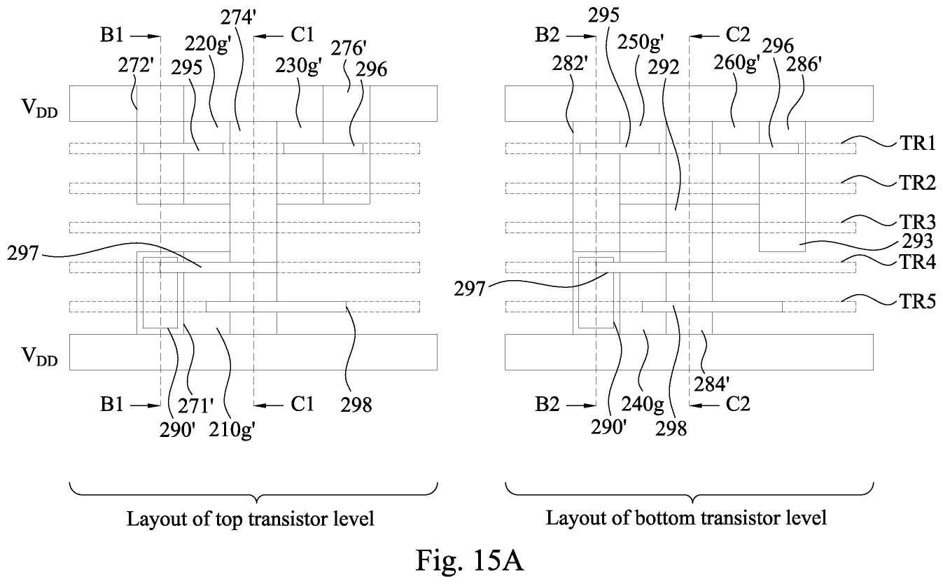

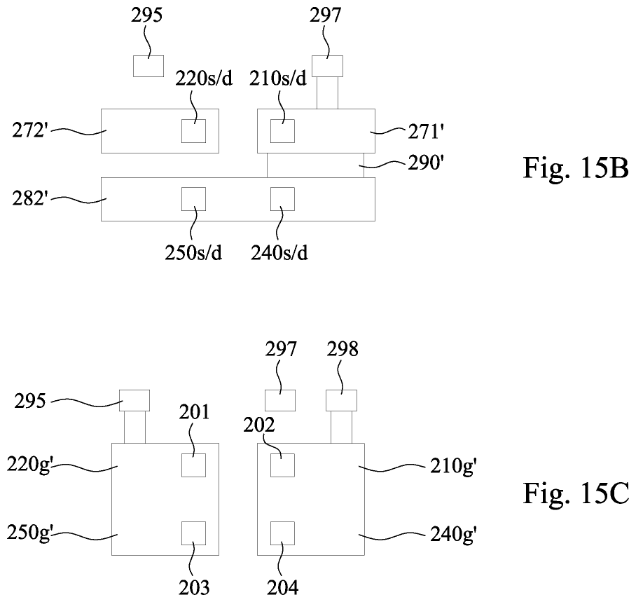

FIG. 15A is a top view layout diagram illustrating routing congestion improvement of an AOI21 cell in accordance with some embodiments of the present disclosure, wherein FIG. 15A illustrates a combined layout including a layout of top transistor level and a layout of bottom transistor level. FIG. 15B is a cross-sectional view combining a cross-sectional cut B1-B1 on the top transistor level and a cross-sectional cut B2-B2 on the bottom transistor level illustrated in FIG. 15A. FIG. 15C is a cross-sectional view combining a cross-sectional cut C1-C1 on the top transistor level and a cross-sectional cut C2-C2 on the bottom transistor level illustrated in FIG. 15A.

Layout of the top-transistor-level interconnects (e.g., top-transistor-level metal lines 271′, 272′, 274′ and 276′), bottom-transistor-level interconnects (e.g., bottom-transistor-level metal lines 282′, 284′ and 286′), inter-level source/drain via (e.g., via 190′), and gates (e.g., top gates 210g′, 220g′, 230g′, and bottom gates 240g′, 250g′, 260g′) are similar to that of the AOI21 cell as described previously with respect to FIGS. 14A-14F. FIG. 15A further illustrates routing tracks on a BEOL metal layer above the CFETs. The routing tracks within the AOI21 cell includes routing tracks TR1, TR2, TR3, TR4, TR5. Therefore, five routing tracks are available for the AOI21 cell, and only three routing tracks (e.g., tracks TR1, TR4 and TR5) may be used. Thus, no routing congestion is encountered in the AOI21 cell design.

In some embodiments, a BEOL metal line 295 is routed on the routing track TR1 of an imaginary routing grid. The BEOL metal line 295 is electrically coupled to the gates 220g′, 250g′ by using a via, and thus the BEOL metal line 295 can serve as a gate routing for the gates 220g′, 250g′. In some embodiments, a BEOL metal line 296 is routed on the routing track TR1 of an imaginary routing grid and spaced apart from the BEOL metal line 295. The BEOL metal line 296 is electrically coupled to the gates 230g′, 260g′ by using a via below the metal line 296, and thus the BEOL metal line 296 can serve as a gate routing for the gates 230g′, 260g′. In some embodiments, a BEOL metal line 297 is routed on the routing track TR4 of an imaginary routing grid. The BEOL metal line 297 is electrically coupled to a source/drain region 210s/d of top transistor 210, a source/drain region 240s/d of bottom transistor 240, and a source/drain region 250s/d of bottom transistor 250, by using top-transistor-level metal line 271′, inter-level source/drain via 290′, and bottom-transistor-level metal line 282. In some embodiments, a BEOL metal line 298 is routed on the routing track TR5 of an imaginary routing grid. The BEOL metal line 298 is electrically coupled to the gates 210g′, 240g′ by using a via, and thus the BEOL metal line 298 can serve as a gate routing for the gates 210g′, 240g′. In the depicted embodiment, the AOI21 cell uses only two routing tracks (e.g., TR2 and TR5) for gate routing and only one routing track (e.g., TR4) for source/drain routing, and two routing tracks (e.g., TR2 and TR3) are free. Moreover, the track height is reduced. For example, the AOI21 cell have five available routing tracks and two rows of transistors, and thus the equivalent track height is 2.5 T per row, which is less than track height of AOI21 cell designed using single-cell-height architecture.

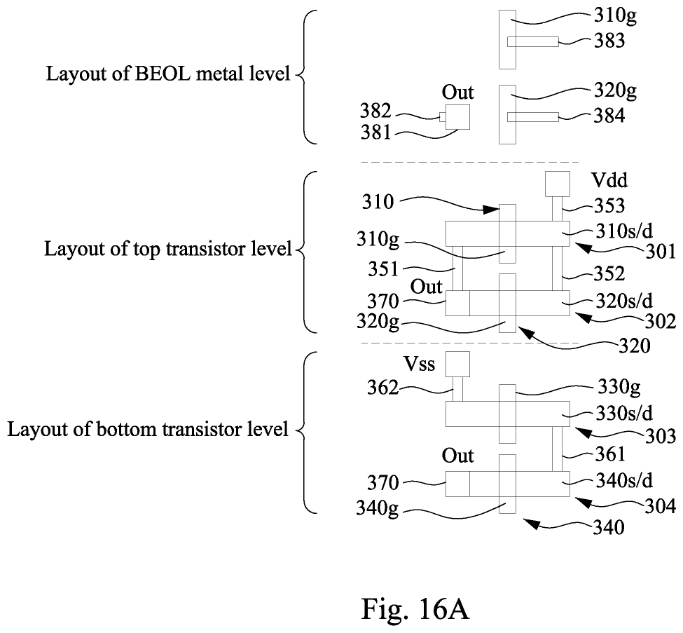

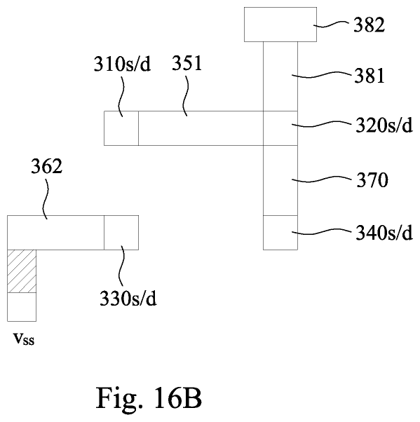

FIGS. 16A and 16B illustrate output node alignment implemented using the bottom-transistor-level interconnects, top-transistor-level interconnects, and inter-level source/drain via. FIG. 16A is a top view layout diagram of a standard cell in accordance with some embodiments of the present disclosure, wherein FIG. 16A illustrates a layout of BEOL metal level, a layout of top transistor level and a layout of bottom transistor level. FIG. 16B is a cross-sectional view combining a cross-section of output node (denoted as “Out”) on the bottom transistor level, a cross-section of output node (denoted as “Out”) on the top transistor level, and a cross-section of output node (denoted as “Out”) on the BEOL metal level illustrated in FIG. 16A.

The standard cell includes top transistors (p-type transistors) 310, 320 and bottom transistors (n-type transistors) 330, 340 disposed below the top transistors 310, 320, respectively. The p-type transistor 310 is arranged in an upper row, and the n-type transistor 330 is arranged in the lower row and vertically stacked below the p-type transistor 310. The p-type transistor 320 are arranged in a lower row, and the n-type transistor 340 is arranged in the lower row and vertically stacked below the p-type transistor 320. The p-type transistor 310 includes a gate 310g, and p-type source/drain regions 310s/d on opposite sides of the gate 310g. The p-type transistor 320 includes a gate 320g, and p-type source/drain regions 320s/d on opposite sides of the gate 320g. The n-type transistor 330 is disposed directly below the p-type transistor 310 and includes a gate 330g, and n-type source/drain regions 330s/d on opposite sides of the gate 330g. The n-type transistor 340 is disposed directly below the p-type transistor 320 and includes a gate 340g, and n-type source/drain regions 340s/d on opposite sides of the gate 340g.

First one of source/drain regions 310s/d of the p-type transistor 310 is electrically coupled to first one of source/drain regions 320s/d of the p-type transistor 320 by using a top-transistor-level metal line 351. The first one of source/drain regions 320s/d serves as an output node of the p-type transistors of the standard cell. The first one of source/drain regions 320s/d is electrically coupled to a first one of source/drain regions 340s/d of the n-type transistor 340 by using an inter-level source/drain via 370. The first one of source/drain regions 340s/d of the n-type transistor 340 serves as an output node of the n-type transistors 330, 340 of the standard cell. A BEOL via 381 is disposed on the first one of source/drain regions 320s/d of the p-type transistor 320 and serves as a BEOL-level output node for standard cell. Because of the top-transistor-level metal lines, bottom-transistor-level metal lines, and the inter-level source/drain via, the output node of p-type transistors 310, 320 can be aligned with the output node of the n-type transistors 330, 340.

A second one of source/drain regions 310s/d of the p-type transistor 310 is electrically coupled to a second one of source/drain regions 320s/d of the p-type transistor 320 in next row by using a top-transistor-level metal line 352. The second one of source/drain regions 310s/d is electrically coupled to the V_{DD} line by using a top-transistor-level metal line 353. A second one of source/drain regions 340s/d of the n-type transistor 340 is electrically coupled to a first one of source/drain regions 330s/d of the n-type transistor 330 in the next row by using a bottom-transistor-level metal line 361. A second one of the source/drain regions 330s/d is electrically coupled to the V_{SS} line by using a bottom-transistor-level metal line 362 and a backside via below the bottom-transistor-level metal line 362.

The PFET gate 310g and the NFET gate 330g share a same gate structure that surrounds a p-channel in a top semiconductor layer 301 and an n-channel in a bottom semiconductor layer 303. Similarly, the PFET gate 320g and the NFET gate 340g share a same gate structure that surrounds a p-channel in the top semiconductor layer 302 and an n-channel in the bottom semiconductor layer 304. In the BEOL metal level, a BEOL metal line 383 is electrically coupled to the gate structure comprising the PFET gate 310g and the NFET gate 330g, a BEOL metal line 384 is electrically coupled to the gate structure comprising the PFET gate 320g and the NFET gate 340g, and a BEOL metal line 382 is electrically coupled to the output node via 381.

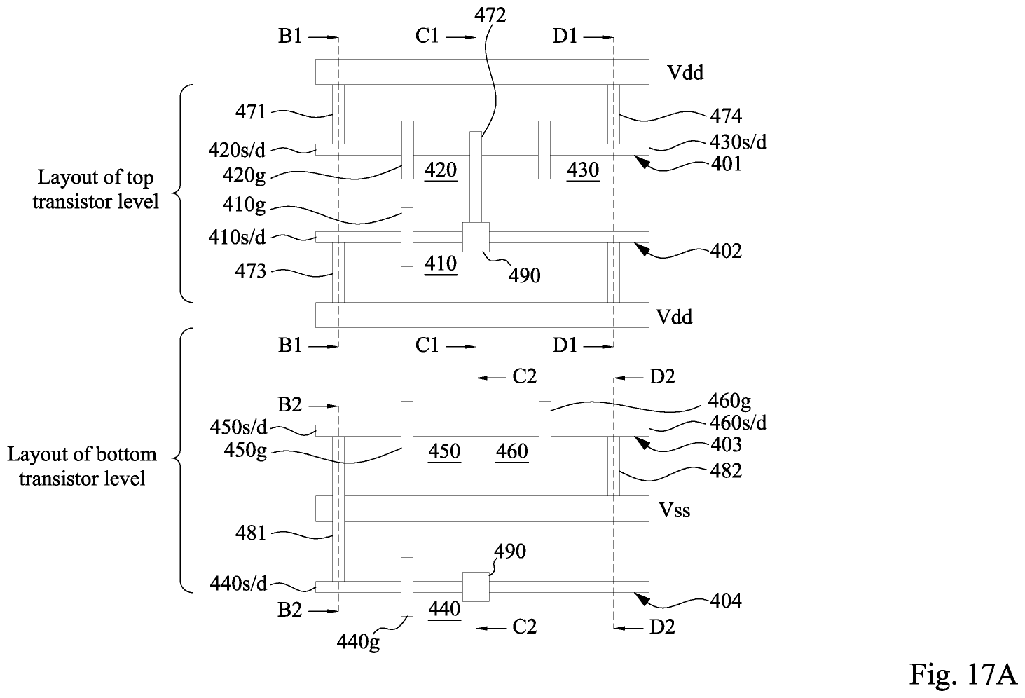

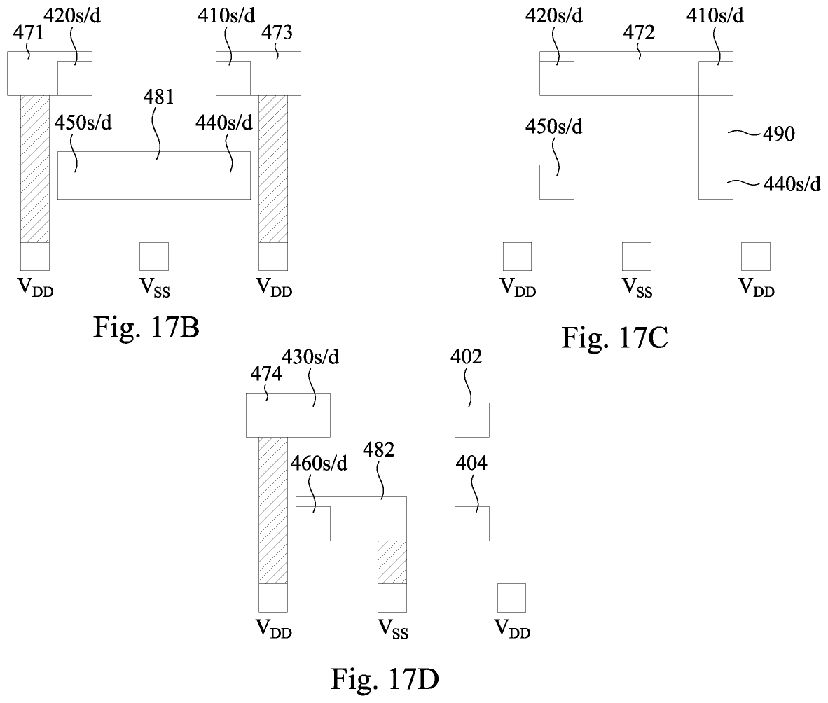

FIG. 17A is a top view layout diagram of a NAND3 logic cell according to some embodiments of the present disclosure, wherein FIG. 17A illustrates a combined layout including a layout of top transistor level and a layout of bottom transistor level. FIG. 17B is a cross-sectional view combining a cross-sectional cut B1-B1 on the top transistor level and a cross-sectional cut B2-B2 on the bottom transistor level illustrated in FIG. 17A. FIG. 17C is a cross-sectional view combining a cross-sectional cut C1-C1 on the top transistor level and a cross-sectional cut C2-C2 on the bottom transistor level illustrated in FIG. 17A. FIG. 17D is a cross-sectional view combining a cross-sectional cut D1-D1 on the top transistor level and a cross-sectional cut D2-D2 on the bottom transistor level illustrated in FIG. 17A.

The NAND3 cell is a DCH cell having a cell height that is twice the pitch between two power supply lines, V_{DD} and V_{SS}. The DCH cell includes two rows of CFETs. The upper row of CFETs is formed using a top semiconductor layer 401 as PFET channels and using a bottom semiconductor layer 403 as NFET channels, and the lower row of CFET is formed using a top semiconductor layer 402 as PFET channels and using a bottom semiconductor layer 404 as NFET channels.

The NAND3 logic cell includes top transistors (p-type transistors) 410, 420, 430, and bottom transistors (n-type transistors) 440, 450, and 460 disposed below the top transistors 410, 420, and 430, respectively. The p-type transistors 420 and 430 are arranged in an upper row, and the n-type transistors 450 and 460 are arranged in the upper row and vertically stacked below the p-type transistors 420 and 430. The p-type transistor 410 is arranged in a lower row, and the n-type transistor 440 is arranged in the lower row and vertically stacked below the p-type transistor 410.

The p-type transistor 410 includes a gate 410g, and p-type source/drain regions 410s/d on opposite sides of the gate 410g. The p-type transistor 420 includes a gate 420g, and p-type source/drain regions 420s/d on opposite sides of the gate 420g. The p-type transistor 430 includes a gate 430g, and p-type source/drain regions 430s/d on opposite sides of the gate 430g. The n-type transistor 440 is disposed directly below the p-type transistor 410 and includes a gate 440g, and n-type source/drain regions 440s/d on opposite sides of the gate 440g. The n-type transistor 450 is disposed directly below the p-type transistor 420 and includes a gate 450g, and n-type source/drain regions 450s/d on opposite sides of the gate 450g. The n-type transistor 460 is disposed directly below the p-type transistor 430 and includes a gate 460g, and n-type source/drain regions 460s/d on opposite sides of the gate 460g.

First one of source/drain regions 420s/d is electrically coupled to V_{DD} line by using a top-transistor-level metal line 471. Second one of source/drain regions 420s/d is electrically coupled to a first one of source/drain regions 410s/d in next row by using a top-transistor-level metal line 472. The first one of source/drain regions 410s/d of the p-type transistor 410 is electrically coupled to a first one of source/drain regions 440s/d of the n-type transistor 440 by using an inter-level source/drain via 490. A second one of source/drain regions 410s/D is electrically coupled to V_{DD} line by using a top-transistor-level metal line 473. A first one of source/drain regions 430s/d and the second one of source/drain regions 420 are a shared source/drain region that is electrically coupled to the first one of source/drain regions 410s/d in next row by using the top-transistor-level metal line 472. A second one of source/drain regions 430s/d is electrically coupled to V_{DD} line by using a top-transistor-level metal line 474.

A second one of source/drain regions 440s/d of the n-type transistor 440 is electrically coupled to a first one of source/drain regions 450s/d of the n-type transistor 450 by using a bottom-transistor-level metal line 481. A second one of source/drain regions 450s/d of the n-type transistor 450 and a first one of source/drain regions 460s/d are a shared source/drain region. A second one of source/drain regions 460s/d is electrically coupled to V_{SS} line by using a bottom-transistor-level metal line 482.

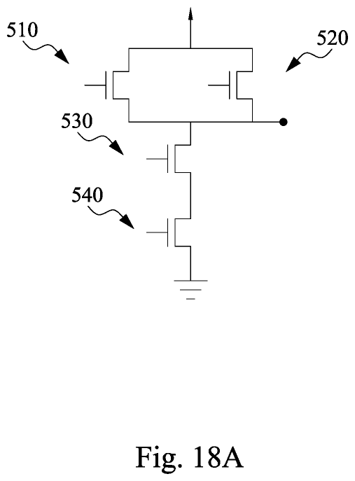

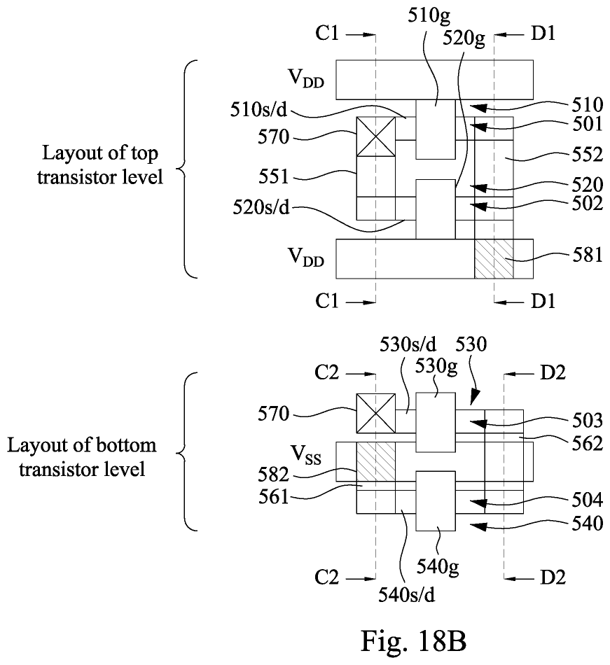

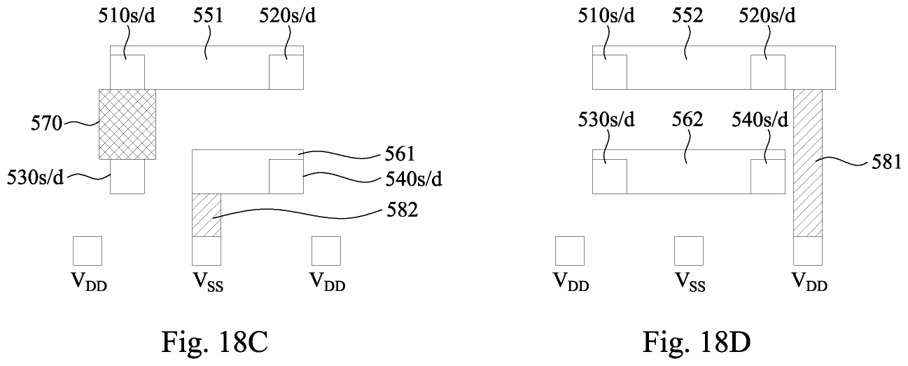

FIG. 18A is a circuit diagram of a NAND logic gate. FIG. 18B is a top view layout diagram of a NAND cell implemented using the DCH standard cell design in accordance with some embodiments of the present disclosure, wherein FIG. 18B illustrates a combined layout including a layout of top transistor level and a layout of bottom transistor level. FIG. 18C is a cross-sectional view combining a cross-sectional cut C1-C1 on the top transistor level and a cross-sectional cut C2-C2 on the bottom transistor level illustrated in FIG. 18B. FIG. 18D is a cross-sectional view combining a cross-sectional cut D1-D1 on the top transistor level and a cross-sectional cut D2-D2 on the bottom transistor level illustrated in FIG. 18B.

The NAND cell is a DCH cell having a cell height that is twice the pitch between two power supply lines, V_{DD} and V_{SS}. The DCH cell includes two rows of CFETs. The upper row of CFETs is formed using a top semiconductor layer 501 as PFET channels and using a bottom semiconductor layer 503 as NFET channels, and the lower row of CFETs is formed using a top semiconductor layer 502 as PFET channels and using a bottom semiconductor layer 504 as NFET channels.

The NAND logic cell includes top transistors (p-type transistors) 510, 520 and bottom transistors (n-type transistors) 530, 540 disposed below the top transistors 510, 520, respectively. The p-type transistor 510 is arranged in an upper row, and the n-type transistor 530 is arranged in the upper row and vertically stacked below the p-type transistor 510. The p-type transistor 520 is arranged in a lower row, and the n-type transistor 540 is arranged in the lower row and vertically stacked below the p-type transistor 520.

The p-type transistor 510 includes a gate 510g, and p-type source/drain regions 510s/d on opposite sides of the gate 510g. The p-type transistor 520 includes a gate 520g, and p-type source/drain regions 520s/d on opposite sides of the gate 520g. The n-type transistor 530 is disposed directly below the p-type transistor 510 and includes a gate 530g, and n-type source/drain regions 530s/d on opposite sides of the gate 530g. The n-type transistor 540 is disposed directly below the p-type transistor 520 and includes a gate 540g, and n-type source/drain regions 540s/d on opposite sides of the gate 540g.

First one of source/drain regions 510s/d of the p-type transistor 510 is electrically coupled to a first one of source/drain regions 530s/d of the n-type transistor 530 by using an inter-level via 570. Firs one of source/drain regions 520s/d of the p-type transistor 520 is electrically coupled to the first one of source/drain regions 510s/d of the p-type transistor 510 by using a top-transistor-level metal line 551. A top-transistor-level metal line 552 electrically connecting a second one of source/drain regions 510s/d of the p-type transistor 510 and a second one of source/drain regions 520s/d of the p-type transistor 520 to a V_{DD} line by using a via 581.

Second one of source/drain regions 530s/d of the n-type transistor 530 is electrically coupled to a first one of source/drain regions 540s/d of the n-type transistor 540 in next row by using a bottom-transistor-level metal line 562. A second one of source/drain regions 540s/d of the n-type transistor 540 is electrically coupled to V_{SS} line by using a bottom-transistor-level metal line 561 and a via 582 below the metal line 561.

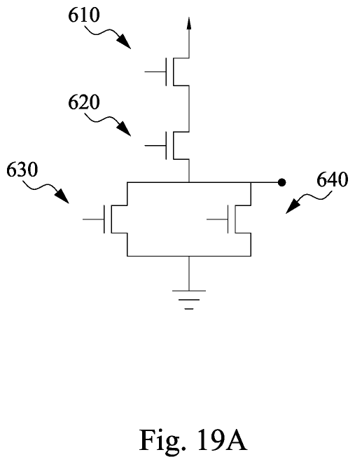

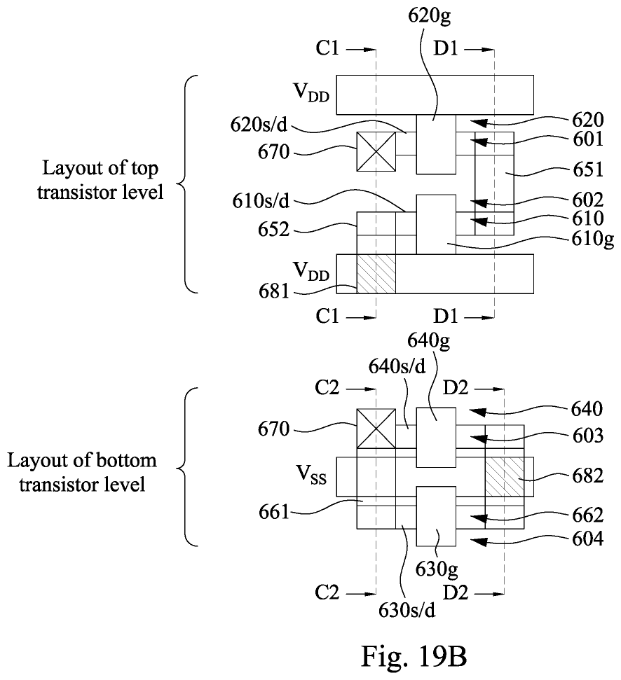

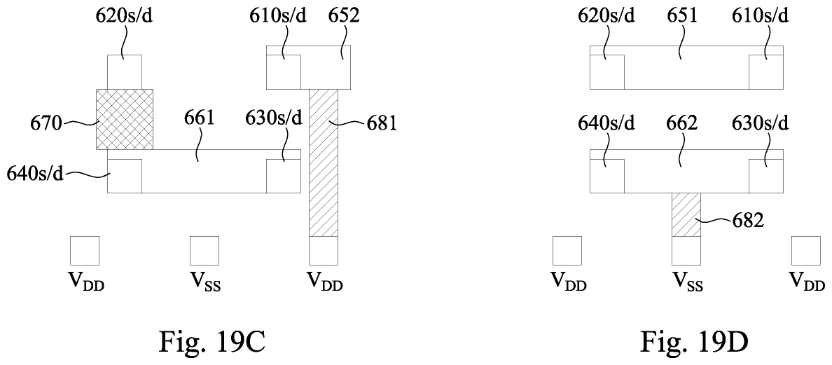

FIG. 19A is a circuit diagram of a NOR logic gate. FIG. 19B is a top view layout diagram of a NOR cell implemented using the DCH standard cell design in accordance with some embodiments of the present disclosure, wherein FIG. 19B illustrates a combined layout including a layout of top transistor level and a layout of bottom transistor level. FIG. 19C is a cross-sectional view combining a cross-sectional cut C1-C1 on the top transistor level and a cross-sectional cut C2-C2 on the bottom transistor level illustrated in FIG. 19B. FIG. 19D is a cross-sectional view combining a cross-sectional cut D1-D1 on the top transistor level and a cross-sectional cut D2-D2 on the bottom transistor level illustrated in FIG. 19B.

The NOR cell is a DCH cell having a cell height that is twice the pitch between two power supply lines, V_{DD} and V_{SS}. The DCH cell includes two rows of CFETs. The upper row of CFETs is formed using a top semiconductor layer 601 as PFET channels and using a bottom semiconductor layer 603 as NFET channels, and the lower row of CFETs is formed using a top semiconductor layer 602 as PFET channels and using a bottom semiconductor layer 604 as NFET channels.

The NOR logic cell includes top transistors (p-type transistors) 610, 620 and bottom transistors (n-type transistors) 630, 640 disposed below the top transistors 610, 620, respectively. The p-type transistor 610 is arranged in a lower row, and the n-type transistor 630 is arranged in the lower row and vertically stacked below the p-type transistor 610. The p-type transistor 620 is arranged in an upper row, and the n-type transistor 640 is arranged in the upper row and vertically stacked below the p-type transistor 620.

The p-type transistor 610 includes a gate 610g, and p-type source/drain regions 610s/d on opposite sides of the gate 610g. The p-type transistor 620 includes a gate 620g, and p-type source/drain regions 620s/d on opposite sides of the gate 620g. The n-type transistor 630 is disposed directly below the p-type transistor 610 and includes a gate 630g, and n-type source/drain regions 630s/d on opposite sides of the gate 630g. The n-type transistor 640 is disposed directly below the p-type transistor 620 and includes a gate 640g, and n-type source/drain regions 640s/d on opposite sides of the gate 640g.

First one of source/drain regions 610s/d of the p-type transistor 610 is electrically coupled to V_{DD} line by using a top-transistor-level metal line 652 and a via 681 below the metal line 652. Second one of source/drain regions 610s/d of the p-type transistor 610 is electrically coupled to a first one of source/drain regions 620s/d of the p-type transistor 620 in next row by using a top-transistor-level metal line 651. Second one of the source/drain regions 620s/d of the p-type transistor 620 is electrically coupled to a first one of source/drain regions 640s/d of the n-type transistor 640 by using an inter-level source/drain via 670.

The first one of source/drain regions 640s/d of the n-type transistor 640 is electrically coupled to a first one of source/drain regions 630s/d of the n-type transistor 630 by using a bottom-transistor-level metal line 661. A bottom-transistor-level metal line 662 electrically connects a second one of source/drain regions 640s/d of the n-type transistor 640 and a second one of source/drain regions 630s/d of the n-type transistor 630 to V_{SS} line by using a via 682 below the metal line 662.

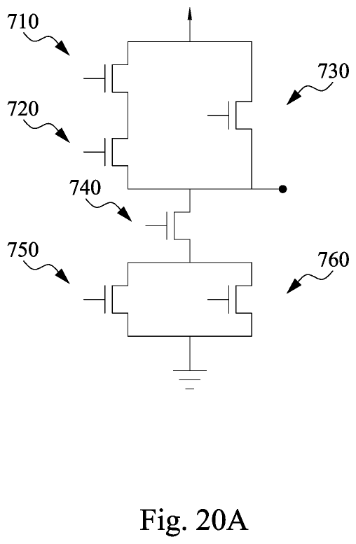

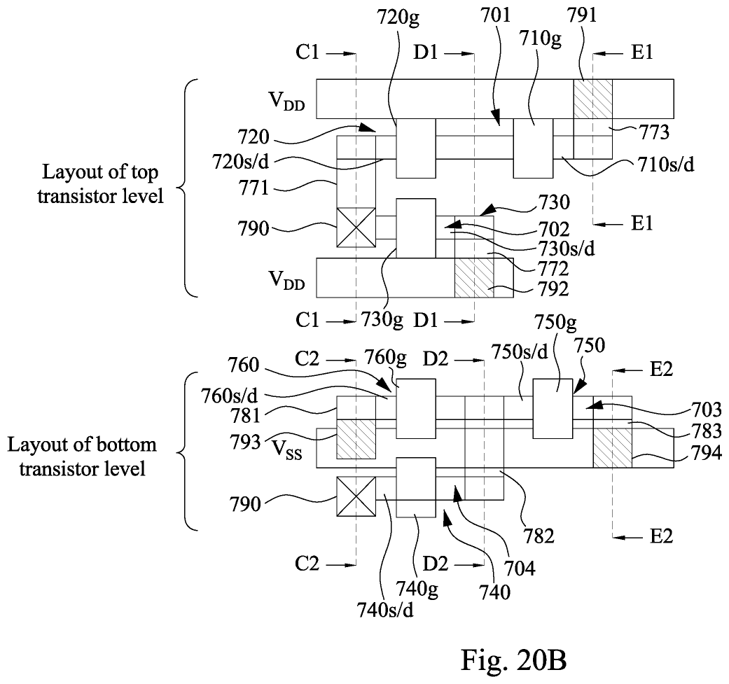

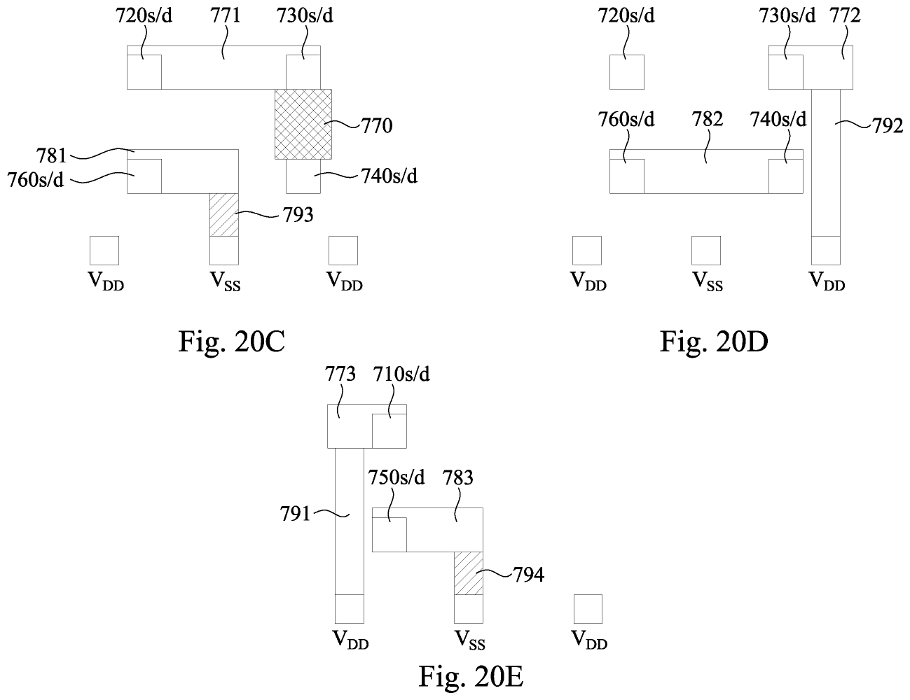

FIG. 20A is a circuit diagram of a OR-AND-invert (OAI) 21 logic gate (also called OAI21 logic gate). FIG. 20B is a top view layout diagram of an OAI21 logic cell implemented using the DCH standard cell design in accordance with some embodiments of the present disclosure, wherein FIG. 20B illustrates a combined layout including a layout of top transistor level and a layout of bottom transistor level. FIG. 20C is a cross-sectional view combining a cross-sectional cut C1-C1 on the top transistor level and a cross-sectional cut C2-C2 on the bottom transistor level illustrated in FIG. 20B. FIG. 20D is a cross-sectional view combining a cross-sectional cut D1-D1 on the top transistor level and a cross-sectional cut D2-D2 on the bottom transistor level illustrated in FIG. 20B. FIG. 20E is a cross-sectional view combining a cross-sectional cut E1-E1 on the top transistor level and a cross-sectional cut E2-E2 on the bottom transistor level illustrated in FIG. 20B.

As illustrated in FIG. 20B, the OAI21 logic cell is a DCH cell having a cell height that is twice the pitch between two power supply lines, V_{DD} and V_{SS}. The DCH cell includes two rows of CFETs. The upper row of CFETs is formed using a top semiconductor layer 701 as PFET channels and using a bottom semiconductor layer 703 as NFET channels, and the lower row of CFETs is formed using a top semiconductor layer 702 as PFET channels and using a bottom semiconductor layer 704 as NFET channels.

The OAI21 logic cell includes top transistors (p-type transistors) 710, 720, 730, and bottom transistors (n-type transistors) 740, 750, and 760 disposed below the top transistors 730, 710, and 720, respectively. The p-type transistors 720 and 710 are arranged in an upper row, and the n-type transistors 760 and 750 are arranged in the upper row and vertically stacked below the p-type transistors 720 and 710. The p-type transistor 730 are arranged in a lower row, and the n-type transistor 740 is arranged in the lower row and vertically stacked below the p-type transistor 730.

The p-type transistor 710 includes a gate 710g, and p-type source/drain regions 710s/d on opposite sides of the gate 710g. The p-type transistor 720 includes a gate 720g, and p-type source/drain regions 720s/d on opposite sides of the gate 720g. The p-type transistor 730 includes a gate 730g, and p-type source/drain regions 730s/d on opposite sides of the gate 730g. The n-type transistor 740 is disposed directly below the p-type transistor 730 and includes a gate 740g, and n-type source/drain regions 740s/d on opposite sides of the gate 740g. The n-type transistor 750 is disposed directly below the p-type transistor 710 and includes a gate 750g, and n-type source/drain regions 750s/d on opposite sides of the gate 750g. The n-type transistor 760 is disposed directly below the p-type transistor 720 and includes a gate 760g, and n-type source/drain regions 760s/d on opposite sides of the gate 760g.

First one of source/drain regions 710s/d of the p-type transistor 710 is electrically coupled to V_{DD} line by using a top-transistor-level metal line 773 and a via 791 vertically extending between the metal line 773 and V_{DD} line. Second one of source/drain regions 710s/d of the p-type transistor 710 and a first one of the source/drain regions 720s/d of the p-type transistor 720 are a shared source/drain region. Second one of source/drain regions 720s/d is electrically coupled to a first one of source/drain regions 730s/d of the p-type transistor 730 by using a top-transistor-level metal line 771. Second one of source/drain regions 730s/d is electrically coupled to another V_{DD} line by using a top-transistor-level metal line 772 and a via 792 vertically extending between the metal line 772 and the V_{DD} line.

Inter-level source/drain via 790 electrically couples the first one of source/drain regions 730s/d of the p-type transistor 730 to a first one of source/drain regions 740s/d of the n-type transistor 740. Second one of source/drain regions 740s/d of the n-type transistor 740 is electrically coupled to a first one of source/drain regions 750s/d of the n-type transistor 750 and a first one of source/drain regions 760 s/d of the n-type transistor 760 by using a bottom-transistor-level metal line 782. The first one of source/drain regions 750s/d of the n-type transistor 750 and the first one of source/drain regions 760s/d of the n-type transistor 760 are a shared source/drain region. Second one of the source/drain regions 750s/d of the n-type transistor 750 is electrically coupled to V_{SS} line by using a bottom-transistor-level metal line 783 and a via 794 vertically extending the metal line 783 and V_{SS} line. Second one of the source/drain regions 760s/d of the n-type transistor 760 is electrically coupled to V_{SS} line by using a bottom-transistor-level metal line 781 and a via 793 vertically extending the metal line 781 and V_{SS} line.

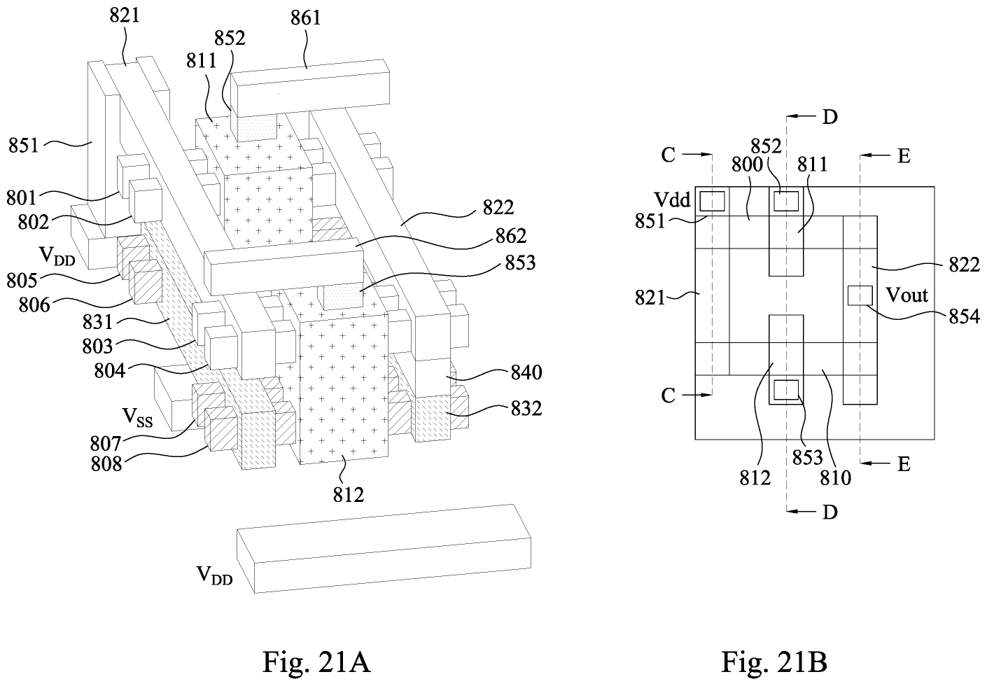

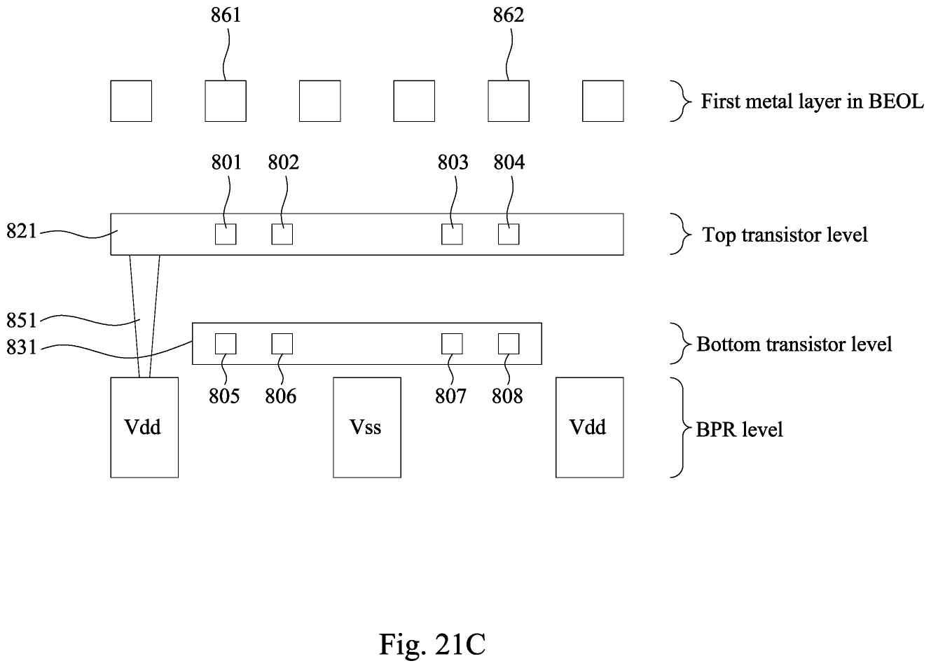

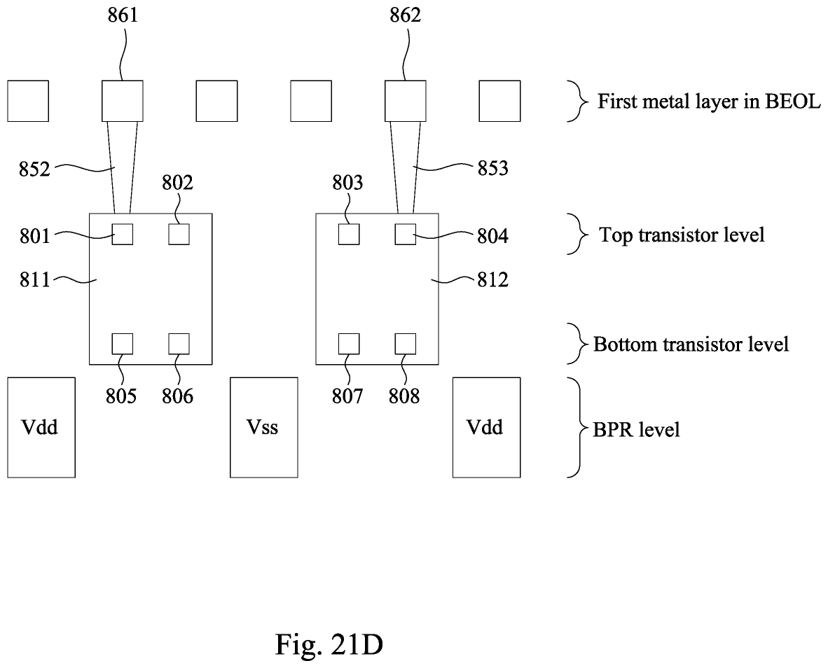

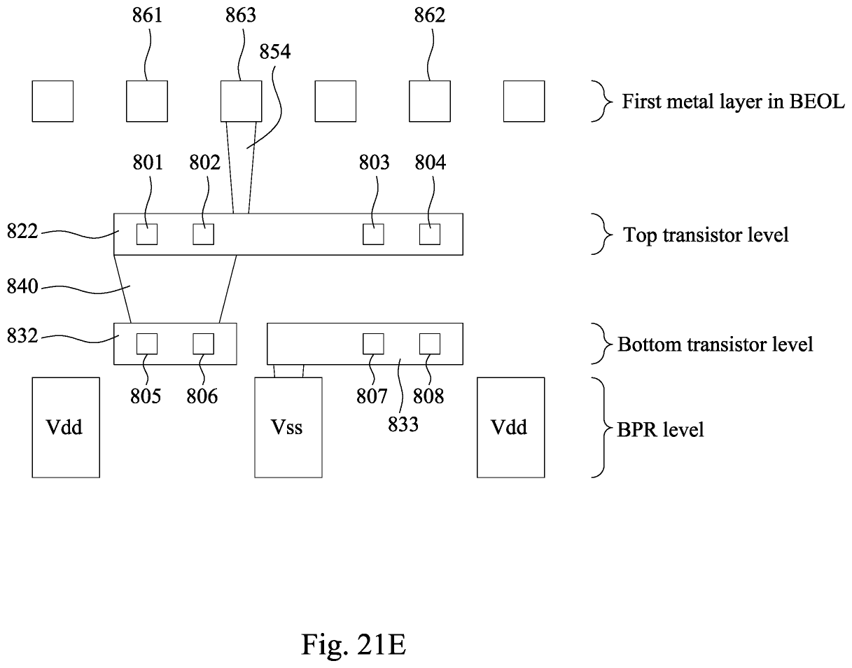

FIG. 21A is a three-dimensional (3D) layout diagram of a NAND logic cell implemented using the DCH standard cell design in accordance with some embodiments of the present disclosure. FIG. 21B is a top view layout of the NAND logic cell. FIG. 21C is a cross-sectional view of a cross-sectional cut C-C illustrated in FIG. 21B. FIG. 21D is a cross-sectional view of a cross-sectional cut D-D illustrated in FIG. 21B. FIG. 21E is a cross-sectional view of a cross-sectional cut E-E illustrated in FIG. 21B.

The NAND cell is a DCH cell having a cell height that is twice the pitch between two power supply lines, V_{DD} and V_{SS}. The DCH cell includes two rows of CFETs. The upper row of CFETs is formed using two top semiconductor nanostructures (e.g., nanowires, nanosheets) 801, 802 as PFET channels and using two bottom semiconductor nanostructures 805, 806 as NFET channels, and the lower row of CFETs is formed using two semiconductor nanostructures 803, 804 as PFET channels and using two semiconductor nanostructures 807, 808 as NFET channels. A gate structures 811 wraps around the top semiconductor nanostructures 801, 802 to form a PFET with the top semiconductor nanostructures 801, 802. The gate structure 811 also wraps around the bottom semiconductor nanostructures 805, 806 to an NFET with the bottom semiconductor nanostructures 805, 806. A gate structures 812 wraps around the top semiconductor nanostructures 803, 804 to form a PFET with the top semiconductor nanostructures 803, 804. The gate structure 812 also wraps around the bottom semiconductor nanostructures 807, 808 to an NFET with the bottom semiconductor nanostructures 807, 808. In FIG. 21B, for the sake of clarity and simplicity, the top semiconductor nanostructures 801, 802 and bottom semiconductor nanostructures 805, 806 are illustrated together as a nanostructure 800, and the top semiconductor nanostructures 803, 804 and the bottom semiconductor nanostructures 807, 808 are illustrated together as a nanostructure 810.

A top-transistor-level metal line 821 extend across first source/drain regions in the top semiconductor nanostructures 801-804 to a via 851 that is in contact with a V_{DD} line. A top-transistor-level metal line 822 extend across second source/drain regions in the top semiconductor nanostructures 801-804. A via 854 electrically connects the top-transistor-level metal line 822 to a BEOL metal line 863 that extends in a bottommost metal layer in an BEOL interconnect structure. The via serves as an output node of the NAND cell. A bottom-transistor-level metal line 831 extend across first source/drain regions in the bottom semiconductor nanostructures 805-808. A bottom-transistor-level metal line 832 extend across second source/drain regions of the bottom semiconductor nanostructures 805-806. An inter-level source/drain via 840 electrically connects the bottom-transistor-level metal line 832 to the top-transistor-level metal line 822. A bottom-transistor-level metal line 833 extend across second source/drain regions in the bottom semiconductor nanostructures 807-808 to a via that is in contact with a V_{SS} line. A via 852 electrically connects the gate structure 811 to a BEOL metal line 861, and a via 853 electrically connects the gate structure 812 to a BEOL metal line 862.

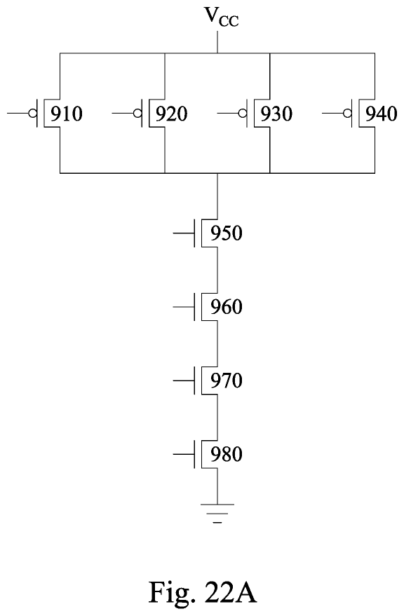

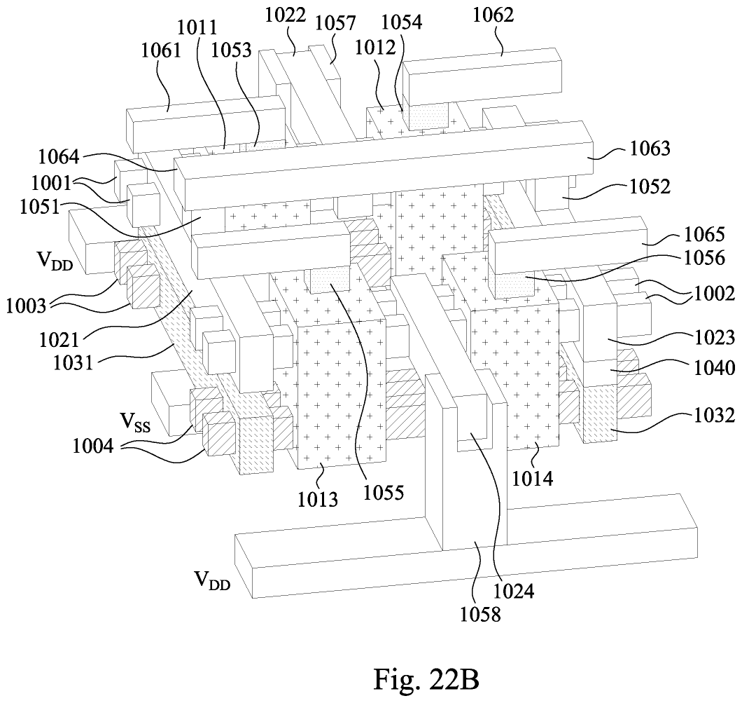

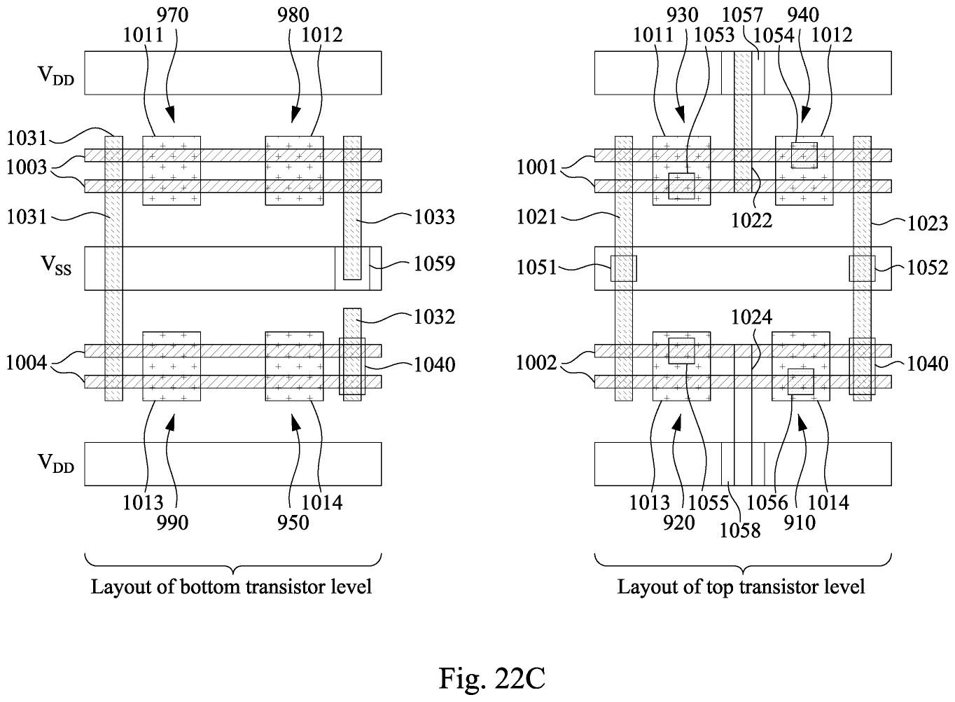

FIG. 22A is a circuit diagram of a NAND4 logic gate. FIG. 22B is a 3D layout diagram of a NAND4 cell implemented using the DCH standard cell design in accordance with some embodiments of the present disclosure. FIG. 22C is a top view layout of the NAND4 cell, wherein FIG. 22C illustrates a combined layout including a layout of top transistor level and a layout of bottom transistor level.

The NAND4 cell is a DCH cell having a cell height that is twice the pitch between two power supply lines, V_{DD} and V_{SS}. The DCH cell includes two rows of CFETs. The upper row of CFETs is formed using two top semiconductor nanostructures (e.g., nanowires, nanosheets) 1001 as PFET channels and using two bottom semiconductor nanostructures 1003 as NFET channels, and the lower row of CFETs is formed using two semiconductor nanostructures 1002 as PFET channels and using two semiconductor nanostructures 1004 as NFET channels. A gate structure 1011 wraps around the top semiconductor nanostructures 1001 to form a PFET 930 with the top semiconductor nanostructures 1001. The gate structure 1011 wraps around the bottom semiconductor nanostructures 1003 to form an NFET 970 with the bottom semiconductor nanostructures 1003. A gate structure 1012 wraps around the top semiconductor nanostructures 1001 to form a PFET 940 with the top semiconductor nanostructures 1001. The gate structure 1012 wraps around the bottom semiconductor nanostructures 1003 to form an NFET 980 with the bottom semiconductor nanostructures 1003. A gate structure 1013 wraps around the top semiconductor nanostructures 1002 to form a PFET 920 with the top semiconductor nanostructures 1002. The gate structure 1013 wraps around the bottom semiconductor nanostructures 1004 to form an NFET 990 with the bottom semiconductor nanostructures 1004. A gate structure 1014 wraps around the top semiconductor nanostructures 1002 to form a PFET 910 with the top semiconductor nanostructures 1002. The gate structure 1014 wraps around the bottom semiconductor nanostructures 1004 to form an NFET 950 with the bottom semiconductor nanostructures 1004.

A bottom-transistor-level metal line 1031 electrically connects a source/drain region of the NFET 970 and a source/drain region of the NFET 990. The NFET 970 and the NFET 980 have a shared source/drain region therebetween. The NFET 980 has a source/drain region electrically coupled to V_{SS} line by using a bottom-transistor-level metal line 1033 and a via 1059 below the metal line 1033. The NFET 990 and the NFET 950 have a shared source/drain region. The NFET 950 has a source/drain region electrically coupled to a source/drain region of the PFET 910 by using a bottom-transistor-level metal line 1032, an inter-level source/drain via 1040 above the bottom-transistor-level metal line 1032, and a top-transistor-level metal line 1023 above the inter-level source/drain via 1040.

The PFET 910 and the PFET 920 have a shared source/drain region electrically coupled to V_{DD} line by using a top-transistor-level metal line 1024 and a via 1058 below the metal line 1024. The PFET 930 and the PFET 940 have a shared source/drain region electrically coupled to another V_{DD} line by using a top-transistor-level metal line 1022 and a via 1057 below the metal line 1022. The top-transistor-level metal line 1023 electrically connects a source/drain region of the PFET 940 and the source/drain region of the PFET 910. A source/drain region of the PFET 920 and a source/drain region of the PFET 930 are electrically coupled to the electrically coupled source/drain regions of PFETs 910, 940 by using a top-transistor-level metal line 1021, a via 1051 on the top-transistor-level metal line 1021, a BEOL metal line 1063, and a via 1052 on the top-transistor-level metal line 1023. Th BEOL metal line 1063 serves as a source/drain routing in BEOL interconnect structure.

A via 1053 is disposed on the gate structure 1011, and a BEOL metal line 1061 extends above the via 1053 to serve as a gate routing. A via 1054 is disposed on the gate structure 1012, and a BEOL metal line 1062 extends above the via 1054 to serve as a gate routing. A via 1055 is disposed on the gate structure 1013, and a BEOL metal line 1064 extends above the via 1055 to serve as a gate routing. A via 1056 is disposed on the gate structure 1014, and a BEOL metal line 1065 extends above the via 1056 to serve as a gate routing.

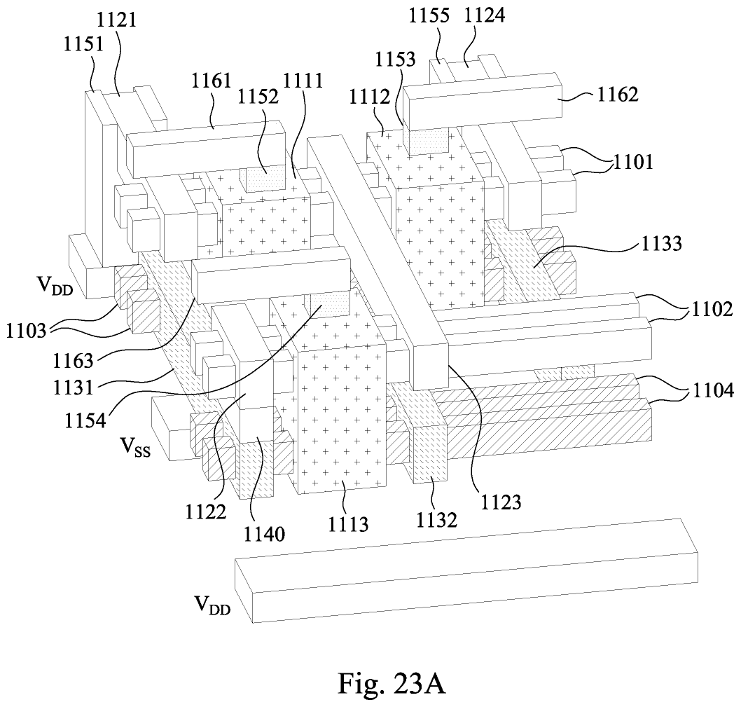

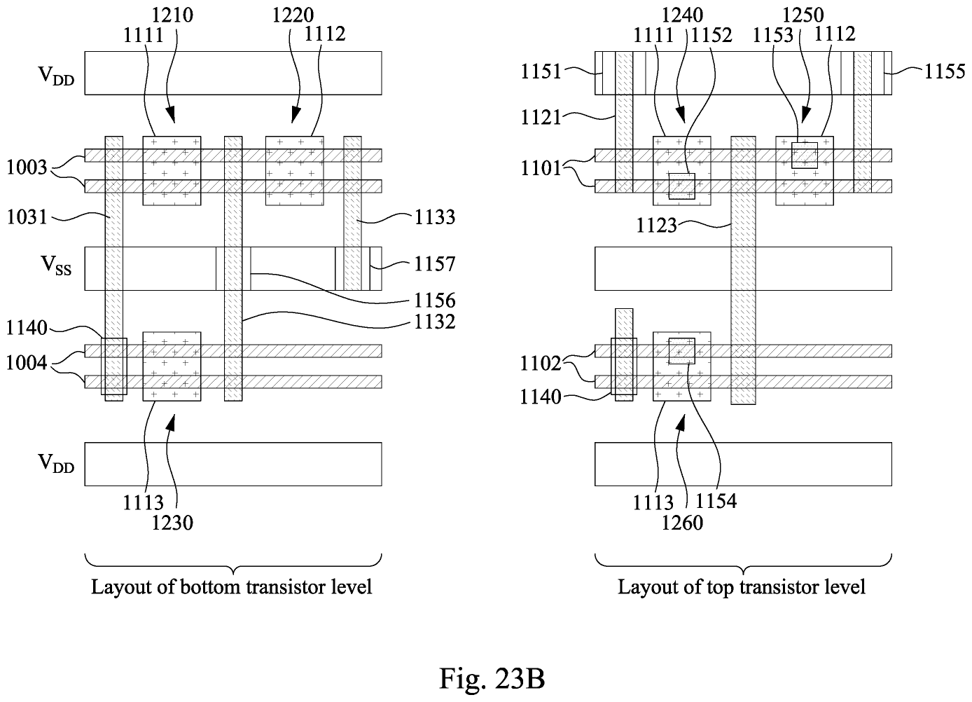

FIG. 23A is a 3D layout diagram of a AOI21 cell implemented using the DCH standard cell design in accordance with some embodiments of the present disclosure. FIG. 23B is a top view layout of the AOI21 cell, wherein FIG. 23B illustrates a combined layout including a layout of top transistor level and a layout of bottom transistor level.

The AOI21 cell is a DCH cell having a cell height that is twice the pitch between two power supply lines, V_{DD} and V_{SS}. The DCH cell includes two rows of CFETs. The upper row of CFETs is formed using two top semiconductor nanostructures (e.g., nanowires, nanosheets) 1101 as PFET channels and using two bottom semiconductor nanostructures 1103 as NFET channels, and the lower row of CFET is formed using two semiconductor nanostructures 1102 as PFET channels and using two semiconductor nanostructures 1104 as NFET channels. A gate structure 1111 wraps around the top semiconductor nanostructures 1101 to form a PFET 1240 with the top semiconductor nanostructures 1101. The gate structure 1111 wraps around the bottom semiconductor nanostructures 1103 to form an NFET 1210 with the bottom semiconductor nanostructures 1103. A gate structure 1112 wraps around the top semiconductor nanostructures 1101 to form a PFET 1250 with the top semiconductor nanostructures 1101. The gate structure 1112 wraps around the bottom semiconductor nanostructures 1103 to form an NFET 1220 with the bottom semiconductor nanostructures 1103. A gate structure 1113 wraps around the top semiconductor nanostructures 1102 to form a PFET 1260 with the top semiconductor nanostructures 1102. The gate structure 1113 wraps around the bottom semiconductor nanostructures 1104 to form an NFET 1230 with the bottom semiconductor nanostructures 1104.

A bottom-transistor-level metal line 1133 electrically connects a source/drain region of the NFET 1220 to V_{SS} line by using a via 1157 below the metal line 1133. The NFET 1220 and the NFET 1210 have a shared source/drain region. A source/drain region of the NFET 1210 is electrically coupled to a source/drain region of the NFET 1230 by using a bottom-transistor-level metal line 1131. A source/drain region of the NFET 1230 is electrically coupled to V_{SS} line by using a via 1156 below the metal line 1132. An inter-level source/drain via 1140 is vertically disposed between the bottom-transistor-level metal line 1131 and a top-transistor-level metal line 1122 that electrically connects a source/drain region of the PFET 1260. Another source/drain region of the PFET 1260 is electrically coupled to a shared source/drain region of the PFETs 1240, 1250 by using a top-transistor-level metal line 1123. A source/drain region of the PFET 1240 is electrically coupled to V_{DD} line by using a top-transistor-level metal line 1121 and a via 1151 below the metal line 1121. A source/drain region of the PFET 1250 is electrically coupled to V_{DD} line by using a top-transistor-level metal line 1124 and a via 1155 below the metal line 1124.

A via 1152 is disposed on the gate structure 1111, and a BEOL metal line 1161 extends above the via 1152 to serve as a gate routing. A via 1153 is disposed on the gate structure 1112, and a BEOL metal line 1162 extends above the via 1153 to serve as a gate routing. A via 1154 is disposed on the gate structure 1113, and a BEOL metal line 1163 extends above the via 1154 to serve as a gate routing.

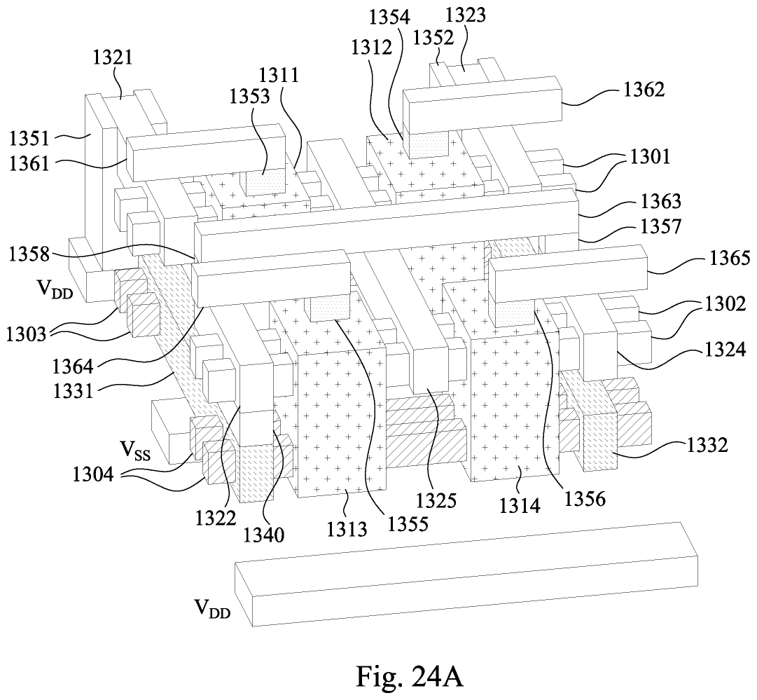

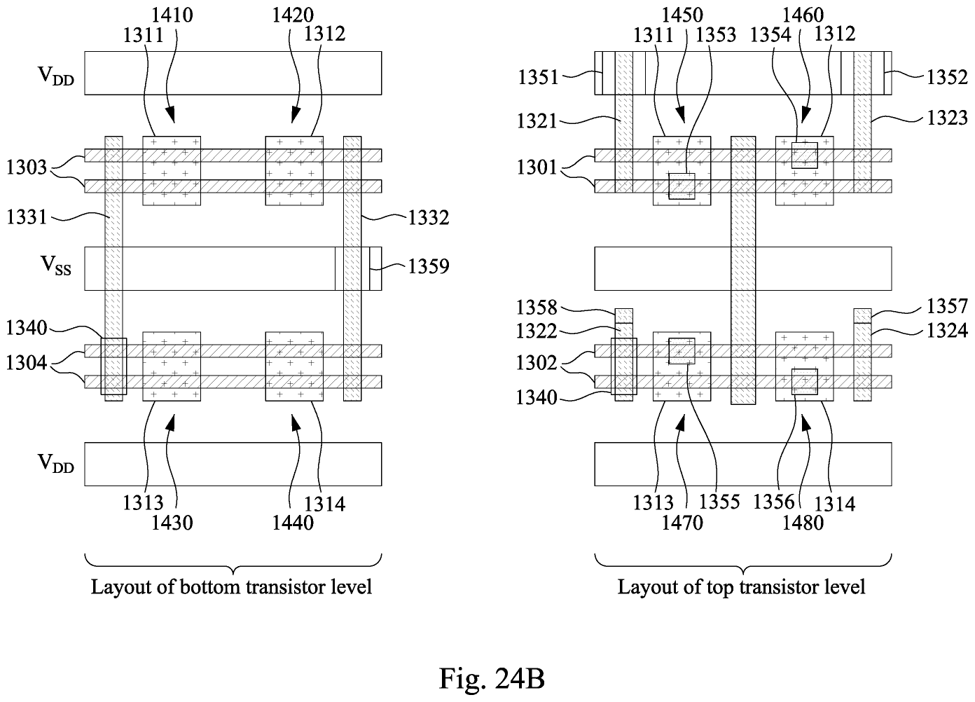

FIG. 24A is a 3D layout diagram of a AOI22 cell implemented using the DCH standard cell design in accordance with some embodiments of the present disclosure. FIG. 24B is a top view layout of the AOI22 cell, wherein FIG. 24B illustrates a combined layout including a layout of top transistor level and a layout of bottom transistor level.

The AOI22 cell is a DCH cell having a cell height that is twice the pitch between two power supply lines, V_{DD} and V_{SS}. The DCH cell includes two rows of CFETs. The upper row of CFETs is formed using two top semiconductor nanostructures (e.g., nanowires, nanosheets) 1301 as PFET channels and using two bottom semiconductor nanostructures 1303 as NFET channels, and the lower row of CFETs is formed using two semiconductor nanostructures 1302 as PFET channels and using two semiconductor nanostructures 1304 as NFET channels. A gate structure 1311 wraps around the top semiconductor nanostructures 1301 to form a PFET 1450 with the top semiconductor nanostructures 1301. The gate structure 1311 wraps around the bottom semiconductor nanostructures 1303 to form an NFET 1410 with the bottom semiconductor nanostructures 1303. A gate structure 1312 wraps around the top semiconductor nanostructures 1301 to form a PFET 1460 with the top semiconductor nanostructures 1301. The gate structure 1312 wraps around the bottom semiconductor nanostructures 1303 to form an NFET 1420 with the bottom semiconductor nanostructures 1303. A gate structure 1313 wraps around the top semiconductor nanostructures 1302 to form a PFET 1470 with the top semiconductor nanostructures 1302. The gate structure 1313 wraps around the bottom semiconductor nanostructures 1304 to form an NFET 1430 with the bottom semiconductor nanostructures 1304. A gate structure 1314 wraps around the top semiconductor nanostructures 1302 to form a PFET 1480 with the top semiconductor nanostructures 1302. The gate structure 1314 wraps around the bottom semiconductor nanostructures 1304 to form an NFET 1440 with the bottom semiconductor nanostructures 1304.

A bottom-transistor-level metal line 1332 electrically connects a source/drain region of the NFET 1420 and a source/drain region of the NFET 1440 to V_{SS} line by using a via 1359 below the metal line 1332. The NFET 1410 and the NFET 1420 have a shared source/drain region. The NFET 1430 and the NFET 1440 have a shared source/drain region. A bottom-transistor-level metal line 1331 electrically connects a source/drain region of the NFET 1410 and a source/drain region of the NFET 1430. An inter-level source/drain via 1340 is vertically disposed between the bottom-transistor-level metal line 1331 and a top-transistor-level metal line 1322 that electrically connects a source/drain region of the PFET 1470. A top-transistor-level metal line 1325 electrically connects a shared source/drain region of the PFETs 1450, 1460 to a shared source/drain region of the PFETs 1470, 1480. A top-transistor-level metal line 1321 electrically connects a source/drain region of the PFET 1450 to V_{DD} line by using a via 1351 below the metal line 1321. A top-transistor-level metal line 1323 electrically connects a source/drain region of the PFET 1460 to V_{DD} line by using a via 1352 below the metal line 1323. A top-transistor-level metal line 1322 is electrically coupled to a source/drain region of the PFET 1480 by using a via 1358 above the metal line 1322, a BEOL metal line 1363, a via 1357 below the BEOL metal line 1363, and a top-transistor-level metal line 1324 disposed on the source/drain region 1480.

A via 1353 is disposed on the gate structure 1311, and a BEOL metal line 1361 extends above the via 1353 to serve as a gate routing. A via 1354 is disposed on the gate structure 1312, and a BEOL metal line 1362 extends above the via 1354 to serve as a gate routing. A via 1355 is disposed on the gate structure 1313, and a BEOL metal line 1364 extends above the via 1355 to serve as a gate routing. A via 1356 is disposed on the gate structure 1314, and a BEOL metal line 1365 extends above the via 1356 to serve as a gate routing.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that routing length and via count for logic cells can be reduced. For example, routing length reduction can be achieved in, e.g., NAND cells, NAND3 cells, NAND4 cells, AOI21 cells, AOI22 cells, and/or other logic cells. Via count reduction can be achieved in, e.g., NAND cells, NOR cells, NAND4 cells, NOR4 cells, AOI21 cells, AOI22 cells, and/or other logic cells. One advantage is that routing congestion in BEOL metal layers can be mitigated. One advantage is that cell area can be reduced. For example, cell area reduction (also called footprint reduction) can be achieved in, e.g., NAND cells, NAND4 cells, AOI21 cells, AOI22 cells, full-adder cells, 32T NAND D-type flip flop (DFF) cells, and/or other logic cells. Moreover, routing of these cells may use at most a bottommost metal layer (also call first metal layer “M1”) of BEOL metal layers, M2 layer routing is not required. One advantage is that RC delay time can be reduced. For example, RC delay reduction can be achieved in, e.g., NAND2 cells, NAND3 cells, NAND4 cells, and/or other logic cells. One advantage is that uniform cell height may be achieved for various logic cells, and thus is compatible with electronic design automation (EDA) tool. One advantage is that the DCH standard cell design is widely applicable to various standard cells including, by way of example and not limitation, NAND, NOR, AOI21, AOI22, OAI21, Transmission gate based XOR, XNOR, MUX, Full Adder, 32T NAND DFF, and/or other suitable cells.

In some embodiments, a semiconductor device having a standard cell comprises a first bottom transistor, a first top transistor, a second bottom transistor, a second top transistor, and a first bottom-transistor-level metal line. The first bottom transistor is in a first row. The first top transistor is disposed above the first bottom transistor in the first row. The first bottom transistor and the first top transistor share a first gate structure. The second bottom transistor is in a second row next to the first row. The second top transistor is disposed above the second bottom transistor in the second row. The second bottom transistor and the second top transistor share a second gate structure. The first bottom-transistor-level metal line extends laterally from a first source/drain region of the first bottom transistor to a source/drain region of the second bottom transistor. In some embodiments, an inter-level source/drain via extends vertically from the source/drain region of the first bottom transistor to a source/drain region of the first top transistor. In some embodiments, one or more power rails are disposed at a level lower than the first and second bottom transistors. In some embodiments, the one or more power rails comprise a first power rail, a second power rail and a third power rail. The first bottom transistor and the first top transistor in the first row is between the first and second power rails from a top view. The second bottom transistor and the second top transistor in the second row is between the second the third power rails from the top view. In some embodiments, the first and third power rails are V_{DD} lines, and the second power rail is a V_{SS} line. In some embodiments, a second bottom-transistor-level metal line extends laterally from a second source/drain region of the first bottom transistor to a position above the V_{SS} line. A via electrically connects the V_{SS} line and the second bottom-transistor-level metal line. In some embodiments, a top-transistor-level metal line extends laterally from a source/drain region of the second top transistor to a position above the V_{DD} line. A via electrically connects the V_{DD} line and the top-transistor-level metal line. In some embodiments, a longitudinal axis of the first gate structure is aligned with a longitudinal axis of the second gate structure. In some embodiments, an output node of the first and second bottom transistors is aligned with an output node of the first and second top transistors.

In some embodiments, a semiconductor device having a standard cell comprises a first bottom transistor, a first top transistor, a second bottom transistor, a second top transistor, and a first top-transistor-level metal line. The first bottom transistor is disposed on a substrate in a first row. The first top transistor is disposed above the first bottom transistor in the first row. The first bottom transistor and the first top transistor share a first gate structure. The second bottom transistor is in a second row next to the first row. The second top transistor is disposed above the second bottom transistor in the second row. The second bottom transistor and the second top transistor share a second gate structure. The first top-transistor-level metal line extends laterally from a first source/drain region of the first top transistor to a first source/drain region of the second top transistor. In some embodiments, the first and second top transistors are p-type transistors, and the first and second bottom transistors are n-type transistors. In some embodiments, an inter-level source/drain via electrically connects a second source/drain region of the first top transistor to a source/drain region of the first bottom transistor. In some embodiments, a bottom-transistor-level metal line extends from the source/drain region of the first bottom transistor to a source/drain region of the second bottom transistor. In some embodiments, a V_{DD} line is inlaid in the substrate, a second top-transistor-level metal line extends from a second source/drain region of the second top transistor to a position above the V_{DD} line, and a via extends vertically from the second top-transistor-level metal line to the V_{DD} line. In some embodiments, V_{SS} line inlaid in the substrate, a bottom-transistor-level metal line extends from a source/drain region of the first bottom transistor to a position above the V_{SS} line, and via extends vertically from the bottom-transistor-level metal line to the V_{SS} line.

In some embodiments, a method comprises forming a first bottom semiconductor layer and a second bottom semiconductor layer over a substrate, the first and second bottom semiconductor layers are arranged in adjacent rows; forming first bottom source/drain regions on the first bottom semiconductor layer, and second bottom source/drain regions on the second bottom semiconductor layer; forming a first top semiconductor layer above the first bottom semiconductor layer, and a second top semiconductor layer above the second bottom semiconductor layer; forming first top source/drain regions on the first top semiconductor layer, and second top source/drain regions on the second top semiconductor layer; forming an inter-level source/drain via between a first one of the first top source/drain regions and a first one of the first bottom source/drain regions; and forming a first gate structure wrapping around a channel region in the first bottom semiconductor layer and a channel region in the first top semiconductor layer, and forming a second gate structure wrapping around a channel region in the second bottom semiconductor layer and a channel region in the second top semiconductor layer. In some embodiments, the method further comprises forming a bottom-transistor-level metal line interfacing sidewalls of one of the second bottom source/drain regions, and forming a top-transistor-level metal line laterally extending from the first one of the first top source/drain regions to one of the second top source/drain regions. In some embodiments, the inter-level source/drain via is formed prior to forming the first gate structure and the second gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device having a standard cell, comprising:
a first bottom transistor in a first row;
a first top transistor disposed above the first bottom transistor in the first row, the first bottom transistor and the first top transistor sharing a first gate structure;
a second bottom transistor in a second row next to the first row;
a second top transistor disposed above the second bottom transistor in the second row, the second bottom transistor and the second top transistor sharing a second gate structure; and
a first bottom-transistor-level metal line extending laterally from a first source/drain region of the first bottom transistor to a source/drain region of the second bottom transistor.

2. The semiconductor device of claim 1, further comprising:
an inter-level source/drain via extending vertically from the source/drain region of the first bottom transistor to a source/drain region of the first top transistor.

3. The semiconductor device of claim 1, further comprising:
one or more power rails disposed at a level lower than the first and second bottom transistors.

4. The semiconductor device of claim 3, wherein the one or more power rails comprise a first power rail, a second power rail and a third power rail, wherein the first bottom transistor and the first top transistor in the first row is between the first and second power rails from a top view, and wherein the second bottom transistor and the second top transistor in the second row is between the second the third power rails from the top view.

5. The semiconductor device of claim 4, wherein the first and third power rails are V_{DD} lines, and the second power rail is a V_{SS} line.

6. The semiconductor device of claim 5, further comprising:
a second bottom-transistor-level metal line extending laterally from a second source/drain region of the first bottom transistor to a position above the V_{SS} line; and
a via electrically connecting the V_{SS} line and the second bottom-transistor-level metal line.

7. The semiconductor device of claim 5, further comprising:
a top-transistor-level metal line extending laterally from a source/drain region of the second top transistor to a position above the V_{DD} line; and
a via electrically connecting the V_{DD} line and the top-transistor-level metal line.

8. The semiconductor device of claim 1, wherein a longitudinal axis of the first gate structure is aligned with a longitudinal axis of the second gate structure.

9. The semiconductor device of claim 1, wherein an output node of the first and second bottom transistors is aligned with an output node of the first and second top transistors.

10. A semiconductor device having a standard cell, comprising:
a first bottom transistor disposed on a substrate in a first row;
a first top transistor disposed above the first bottom transistor in the first row, the first bottom transistor and the first top transistor sharing a first gate structure;
a second bottom transistor in a second row next to the first row;
a second top transistor disposed above the second bottom transistor in the second row, the second bottom transistor and the second top transistor sharing a second gate structure; and
a first top-transistor-level metal line extending laterally from a first source/drain region of the first top transistor to a first source/drain region of the second top transistor.

11. The semiconductor device of claim 10, wherein the first and second top transistors are p-type transistors.

12. The semiconductor device of claim 10, wherein the first and second bottom transistors are n-type transistors.

13. The semiconductor device of claim 10, further comprising:
an inter-level source/drain via electrically connecting a second source/drain region of the first top transistor to a source/drain region of the first bottom transistor.

14. The semiconductor device of claim 13, further comprising:
a bottom-transistor-level metal line extending from the source/drain region of the first bottom transistor to a source/drain region of the second bottom transistor.

15. The semiconductor device of claim 10, further comprising:
a V_{DD} line inlaid in the substrate;
a second top-transistor-level metal line extending from a second source/drain region of the second top transistor to a position above the V_{DD} line; and
a via extending vertically from the second top-transistor-level metal line to the V_{DD} line.

16. The semiconductor device of claim 10, further comprising:
a V_{SS} line inlaid in the substrate;
a bottom-transistor-level metal line extending from a source/drain region of the first bottom transistor to a position above the V_{SS} line; and
a via extending vertically from the bottom-transistor-level metal line to the V_{SS} line.

17. A method, comprising:
forming a first bottom semiconductor layer and a second bottom semiconductor layer over a substrate, the first and second bottom semiconductor layers are arranged in adjacent rows;
forming first bottom source/drain regions on the first bottom semiconductor layer, and second bottom source/drain regions on the second bottom semiconductor layer;
forming a first top semiconductor layer above the first bottom semiconductor layer, and a second top semiconductor layer above the second bottom semiconductor layer;
forming first top source/drain regions on the first top semiconductor layer, and second top source/drain regions on the second top semiconductor layer;
forming an inter-level source/drain via between a first one of the first top source/drain regions and a first one of the first bottom source/drain regions; and
forming a first gate structure wrapping around a channel region in the first bottom semiconductor layer and a channel region in the first top semiconductor layer, and forming a second gate structure wrapping around a channel region in the second bottom semiconductor layer and a channel region in the second top semiconductor layer.

18. The method of claim 17, further comprising:
forming a bottom-transistor-level metal line interfacing sidewalls of one of the second bottom source/drain regions.

19. The method of claim 17, further comprising:
forming a top-transistor-level metal line laterally extending from the first one of the first top source/drain regions to one of the second top source/drain regions.

20. The method of claim 17, wherein the inter-level source/drain via is formed prior to forming the first gate structure and the second gate structure.
